(19) United States
(12) Patent Application Publication
(10) Pub. No.: US 2025/0280545 A1
(43) Pub. Date: Sep. 4, 2025

(54) WORD LINE PROTECTION METHOD IN THE BACKSIDE PROCESS OF A VERTICAL DYNAMIC RANDOM ACCESS MEMORY (DRAM) DEVICE

(71) Applicant: Yangtze Memory Technologies Co., Ltd., Wuhan (CN)

(72) Inventors: Mingliang XU, Wuhan (CN); Ya WANG, Wuhan (CN); He CHEN, Wuhan (CN); Yijie NIE, Wuhan (CN); Zhaoyun TANG, Wuhan (CN); Wenyu HUA, Wuhan (CN)

(73) Assignee: Yangtze Memory Technologies Co., Ltd., Wuhan (CN)

(21) Appl. No.: 18/624,939

(22) Filed: Apr. 2, 2024

Related U.S. Application Data
(63) Continuation of application No. PCT/CN2024/079207, filed on Feb. 29, 2024.

(51) Int. Cl. H10B 63/00; H10B 12/00; H10B 53/30; H10B 63/10

(52) U.S. Cl. CPC H10B 63/34; H10B 12/05; H10B 12/33; H10B 53/30; H10B 63/10

(57) ABSTRACT

A semiconductor memory device includes trench isolations arranged in a bit-line direction, gate structures arranged in a word-line direction perpendicular to the bit-line direction, an array of vertical-transistor channels arranged in a vertical direction perpendicular to the bit-line direction and the word-line direction and separated by the trench isolations and gate structures, top ends of the array of the vertical-transistor channels in each column being connected to a line of semiconductor structure extending in the bit-line direction at a backside of the semiconductor memory device, and air gap tunnels along the word-line direction that each crosses below the line of semiconductor structure and between two neighboring vertical-transistor channels in a first region at the backside of the semiconductor memory device.

### INCORPORATION BY REFERENCE

The present application is a bypass continuation application of International Application No. PCT/CN2024/079207, filed on Feb. 29, 2024, which is incorporated by reference herein in its entirety.

### TECHNICAL FIELD

The present disclosure relates to a semiconductor device and the fabrication process thereof. The semiconductor device can be a vertical gate dynamic random access memory (DRAM) device.

### BACKGROUND

Planar memory cells are scaled to smaller sizes by improving process technology, circuit design, programming algorithm, and fabrication process. However, as feature sizes of the memory cells approach a lower limit, planar process and fabrication techniques become challenging and costly. As a result, memory density for planar memory cells approaches an upper limit. A three-dimensional (3D) memory architecture can be employed to address the density limitation in planar memory cells by using vertical gate transistors.

### SUMMARY

Aspects of the disclosure provide a method of fabricating a semiconductor memory device. The method can include thinning the semiconductor memory device from a backside of the semiconductor device that, at current stage, has trench isolations formed in a bit-line direction, gate structures formed in a word-line direction perpendicular to the bit-line direction, and an array of vertical-transistor channel structures that extend in a vertical direction perpendicular to the bit-line direction and the word-line direction and are separated by the trench isolations and the gate structures, wherein after the thinning, the trench isolations are exposed at the back of the semiconductor device, top ends of the vertical-transistor channel structures in each column along the bit-line direction are connected with a line of semiconductor structure extending along the bit-line direction at the backside of the semiconductor memory device to form a bridge-shaped structure, and the trench isolations separate neighboring bridge-shaped structures, recessing, in a first region of the backside of the semiconductor memory device, the trench isolations between the neighboring bridge-shaped structures to expose the gate structures formed in the word-line direction, etching the gate structures formed in the word-line direction, resulting in tunnels along the respective gate structures, the tunnels crossing below each line of semiconductor structure, filling a space where the trench isolations and the gate structures are etched away with a sacrificial material, covering a portion of the first region of the backside of the semiconductor memory device with an insulation layer, the insulation layer enclosing the sacrificial materials below the insulation layer and between the respective neighboring bridge-shaped structures at the covered portion of the first region, and removing the sacrificial material within the space where the trench isolations and the gate structures are etched away while the portion of the first region is covered with the insulation layer, wherein the sacrificial material enclosed by the insulation layer is removed through the tunnels crossing below respective lines of semiconductor structures.

In one embodiment, the insulation layer covers a second region neighboring the portion of the first region covered by the insulation layer, and the trench isolations in the second region are maintained while the trench isolations in the first region are etched.

In one embodiment, the semiconductor memory device has metal shields formed between every two neighboring channel structures along the word-line direction.

In one embodiment, the method further includes etching the metal shields formed in the word-line direction, resulting in tunnels along the respective metal shield crossing below each line of semiconductor structures, filling the space where the trench isolations and the metal shields are etched away with the sacrificial material, and removing the sacrificial material within the space where the trench isolations and the metal shields are etched away while the portion of the first region is covered with the insulation layer, wherein the sacrificial material enclosed by the insulation layer is removed through the tunnels along the respective metal shields crossing below respective lines of semiconductor structures.

In one embodiment, the method further includes covering surfaces of the space where the trench isolations and the gate structures are etched away with a spacer layer before filling the space where the trench isolations and the gate structures are etched away with the sacrificial material.

In one embodiment, the method further includes forming bit-line structures over the lines of semiconductor structures not covered by the insulation layer in the first region while the portion of the first region is covered with the insulation layer.

Aspects of the disclosure provide a semiconductor memory device. The semiconductor memory device includes trench isolations arranged in a bit-line direction, gate structures arranged in a word-line direction perpendicular to the bit-line direction, an array of vertical-transistor channels arranged in a vertical direction perpendicular to the bit-line direction and the word-line direction and separated by the trench isolations and gate structures, top ends of the array of the vertical-transistor channels in each column being connected to a line of semiconductor structure extending in the bit-line direction at a backside of the semiconductor memory device, and air gap tunnels along the word-line direction that each crosses below the line of semiconductor structure and between two neighboring vertical-transistor channels in a first region at the backside of the semiconductor memory device.

Aspects of the disclosure provide a memory system includes a memory controller, and a semiconductor memory device coupled to the memory controller. The semiconductor memory device includes trench isolations arranged in a bit-line direction, gate structures arranged in a word-line direction perpendicular to the bit-line direction, an array of vertical-transistor channels arranged in a vertical direction perpendicular to the bit-line direction and the word-line direction and separated by the trench isolations and gate structures, top ends of the array of the vertical-transistor channels in each column being connected to a line of semiconductor structure extending in the bit-line direction at a backside of the semiconductor memory device, and air gap tunnels along the word-line direction that each crosses below the line of semiconductor structure and between two neighboring vertical-transistor channels in a first region at the backside of the semiconductor memory device.

### BRIEF DESCRIPTION OF THE DRAWINGS

Aspects of the present disclosure can be understood from the following detailed description when read with the accompanying figures. It is noted that, in accordance with the standard practice in the industry, various features are not drawn to scale. In fact, the dimensions of the various features may be increased or reduced for clarity of discussion.

FIG. 1 illustrates a block diagram of an exemplary system having a memory device, according to some aspects of the present disclosure.

FIG. 2 illustrates a schematic diagram of a memory device including peripheral circuits and an array of memory cells each having a vertical transistor, according to some aspects of the present disclosure.

FIG. 3 illustrates a schematic circuit diagram of a memory device including peripheral circuits and an array of dynamic random-access memory (DRAM) cells, according to some aspects of the present disclosure.

FIG. 4 illustrates a schematic circuit diagram of a memory device including peripheral circuits and an array of phase-change memory (PCM) cells, according to some aspects of the present disclosure.

FIGS. 5A-5B illustrate a fabrication result of overlapping of trench recess regions and insulating layers for bit line formation at a backside of the semiconductor device.

FIGS. 6A-6B illustrate a fabrication result of non-overlapping of trench recess regions and insulating layers for bit line formation at a backside of the semiconductor device.

FIGS. 7A-1˜7A-2/7B-1˜7B-2/7C-1˜7C-2/7D-1˜7D-5/7E/7F-1˜7F-5/7G-1˜7G-7/7H-1˜7H-7/7I-1˜7I-7/7J-1˜7J-7/7K-1˜7K-7 illustrate a fabrication process for forming a memory device according to some aspects of the present disclosure.

FIG. 8 illustrates a flowchart of a fabrication process 800 of forming a semiconductor memory device according to embodiments of the present disclosure.

### DETAILED DESCRIPTION OF EMBODIMENTS

Although specific configurations and arrangements are discussed, it should be understood that this is done for illustrative purposes only. As such, other configurations and arrangements can be used without departing from the scope of the present disclosure. Also, the present disclosure can also be employed in a variety of other applications. Functional and structural features as described in the present disclosures can be combined, adjusted, and modified with one another and in ways not specifically depicted in the drawings, such that these combinations, adjustments, and modifications are within the scope of the present disclosure.

In general, terminology may be understood at least in part from usage in context. For example, the term “one or more” as used herein, depending at least in part upon context, may be used to describe any feature, structure, or characteristic in a singular sense or may be used to describe combinations of features, structures or characteristics in a plural sense. Similarly, terms, such as “a,” “an,” or “the,” again, may be understood to convey a singular usage or to convey a plural usage, depending at least in part upon context. In addition, the term “based on” may be understood as not necessarily intended to convey an exclusive set of factors and may, instead, allow for the existence of additional factors not necessarily expressly described, again, depending at least in part on context.

It should be readily understood that the meaning of “on,” “above,” and “over” in the present disclosure should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (directly on something).

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations), and the spatially relative descriptors used herein may likewise be interpreted accordingly.

As used herein, the term “substrate” refers to a material onto which subsequent material layers are added. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically non-conductive material, such as a glass, a plastic, or a sapphire wafer.

As used herein, the term “layer” refers to a material portion including a region with a thickness. A layer can extend over the entirety of an underlying or overlying structure or may have an extent less than the extent of an underlying or overlying structure. Further, a layer can be a region of a homogeneous or inhomogeneous continuous structure that has a thickness less than the thickness of the continuous structure. For example, a layer can be located between any pair of horizontal planes between, or at, a top surface and a bottom surface of the continuous structure. A layer can extend horizontally, vertically, and/or along a tapered surface. A substrate can be a layer, can include one or more layers therein, and/or can have one or more layers thereupon, thereabove, and/or therebelow. A layer can include multiple layers. For example, an interconnect layer can include one or more conductors and contact layers (in which interconnect lines and/or vertical interconnect access (via) contacts are formed) and one or more dielectric layers.

### I. Memory Devices with Vertical Transistors

Transistors are used as the switch or selecting devices in the memory cells of some memory devices, such as dynamic random access memory (DRAM), phase-change memory (PCM), and ferroelectric DRAM (FRAM). However, the planar transistors commonly used in existing memory cells usually have a horizontal structure with buried word lines in the substrate and bit lines above the substrate. Since the source and drain of a planar transistor are disposed laterally at different locations, which increases the area occupied by the transistor. The design of planar transistors also complicates the arrangement of interconnected structures, such as word lines and bit lines, coupled to the memory cells, for example, limiting the pitches of the word lines and/or bit lines, thereby increasing the fabrication complexity and reducing the production yield. Moreover, because the bit lines and the storage units (e.g., capacitors or PCM elements) are arranged on the same side of the planar transistors (above the transistors and substrate), the bit line process margin is limited by the storage units, and the coupling capacitance between the bit lines and storage units, such as capacitors, are increased. Planar transistors may also suffer from a high leakage current as the saturated drain current keeps increasing, which is undesirable for the performance of memory devices.

On the other hand, the memory cell array and the peripheral circuits for controlling the memory cell array are usually arranged side-by-side in the same plane. As the number of memory cells keeps increasing, to maintain the same chip size, the dimensions of the components in the memory cell array, such as transistors, word lines, and/or bit lines, need to keep decreasing in order not to significantly reduce the memory cell array efficiency.

To address one or more of the aforementioned issues, vertical transistors can replace the planar transistors as the switch and selecting devices in a memory cell array of memory devices (e.g., DRAM, PCM, and FRAM). Compared with planar transistors, the vertically arranged transistors (e.g., the drain and source are overlapped in the plan view) can reduce the area of the transistor as well as simplify the layout of the interconnect structures, e.g., metal wiring the word lines and bit lines, which can reduce the fabrication complexity and improve the yield. For example, the pitches of word lines and/or bit lines can be reduced for case of fabrication. The vertical structures of the transistors also allow the bit lines and storage units, such as capacitors, to be arranged on opposite sides of the transistors in the vertical direction (e.g., one above and on below the transistors), such that the process margin of the bit lines can be increased and the coupling capacitance between the bit lines and the storage units can be decreased.

Also, the memory cell array having vertical transistors and the peripheral circuits of the memory cell array can be formed on different wafers and bonded together in a face-to-face manner. Thus, the thermal budget of fabricating the memory cell array does not affect the fabrication of the peripheral circuits. The stacked memory cell array and peripheral circuits can also reduce the chip size compared with the side-by-side arrangement, thereby improving the array efficiency. In some implementations, more than one memory cell array is stacked over one another using bonding techniques to further increase the array efficiency. In some implementations, the word lines and bit lines are disposed close to the bonding interface due to the vertically arranged transistors, which can be coupled to the peripheral circuits through a large number (e.g., millions) of parallel bonding contacts across the bonding interface can make direct, short-distance (e.g., micron-level) electrical connections between the memory cell array and peripheral circuits to increase the throughput and input/output (I/O) speed of the memory devices.

In some implementations, the vertical transistors disclosed herein include multi-gate transistors (e.g., gate-all-around (GAA) transistors, tri-gate transistors, or double-gate transistors), which can have a larger gate control area to achieve better channel control with a smaller subthreshold swing. Since the channel is fully depleted, the leakage current of multi-gate transistors can be significantly reduced as well. Thus, using multi-gate transistors instead of planar transistors can achieve a much better speed (saturated drain current)/leakage current performance.

In some implementations, the vertical transistors disclosed herein include single-gate transistors (a.k.a. single-side gate transistors) in a mirror-symmetric arrangement with respect to adjacent transistors in the bit line direction as a result of splitting multi-gate transistors (e.g., double-gate transistors) using trench isolations extending along the word line direction. Thus, the memory cell density in the bit line direction can be significantly increased (e.g., doubled) without unduly complicating the fabrication process compared with using processes, such as self-aligned double patterning (SADP). Also, the mirror-symmetric single-gate transistors have a larger process window for word line, bit line, and transistor pitch reduction, compared to either planar transistors or multi-gate vertical transistors, for example, with dual-side or all-around gates.

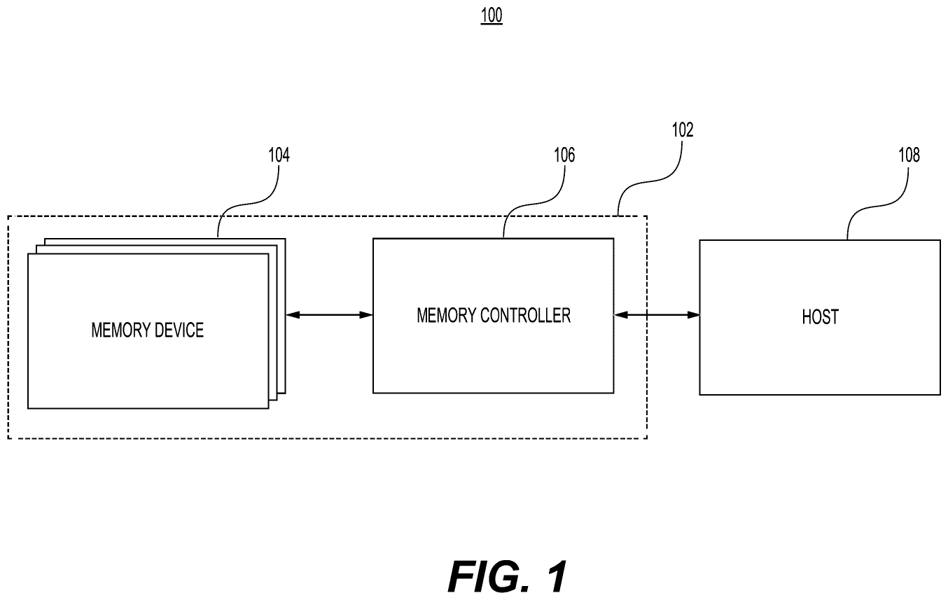

FIG. 1 illustrates a block diagram of system 100 having a memory device, according to some aspects of the present disclosure. System 100 can be a mobile phone, a desktop computer, a laptop computer, a tablet, a vehicle computer, a gaming console, a printer, a positioning device, a wearable electronic device, a smart sensor, a virtual reality (VR) device, an argument reality (AR) device, or any other suitable electronic devices having storage therein. As shown in FIG. 1, system 100 can include a host 108 and a memory system 102 having one or more memory devices 104 and a memory controller 106. Host 108 can be a processor of an electronic device, such as a central processing unit (CPU), or a system-on-chip (SoC), such as an application processor (AP). Host 108 can be configured to send or receive the data to or from memory devices 104.

Memory device 104 can be any memory device disclosed herein. In some implementations, memory device 104 includes an array of memory cells each including a vertical transistor, as described herein.

Memory controller 106 is coupled to memory device 104 and host 108 and is configured to control memory device 104, according to some implementations. Memory controller 106 can manage the data stored in memory device 104 and communicate with host 108. Memory controller 106 can be configured to control operations of memory device 104, such as read, write, and refresh operations. Memory controller 106 can also be configured to manage various functions with respect to the data stored or to be stored in memory device 104 including, but not limited to refresh and timing control, command/request translation, buffer and schedule, and power management. In some implementations, memory controller 106 is further configured to determine the maximum memory capacity that the computer system can use, the number of memory banks, memory type and speed, memory particle data depth and data width, and other important parameters.

Any other suitable functions may be performed by memory controller 106 as well. Memory controller 106 can communicate with an external device (e.g., host 108) according to a particular communication protocol. For example, memory controller 106 may communicate with the external device through at least one of various interface protocols, such as a USB protocol, an MMC protocol, a peripheral component interconnection (PCI) protocol, a PCI-express (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc.

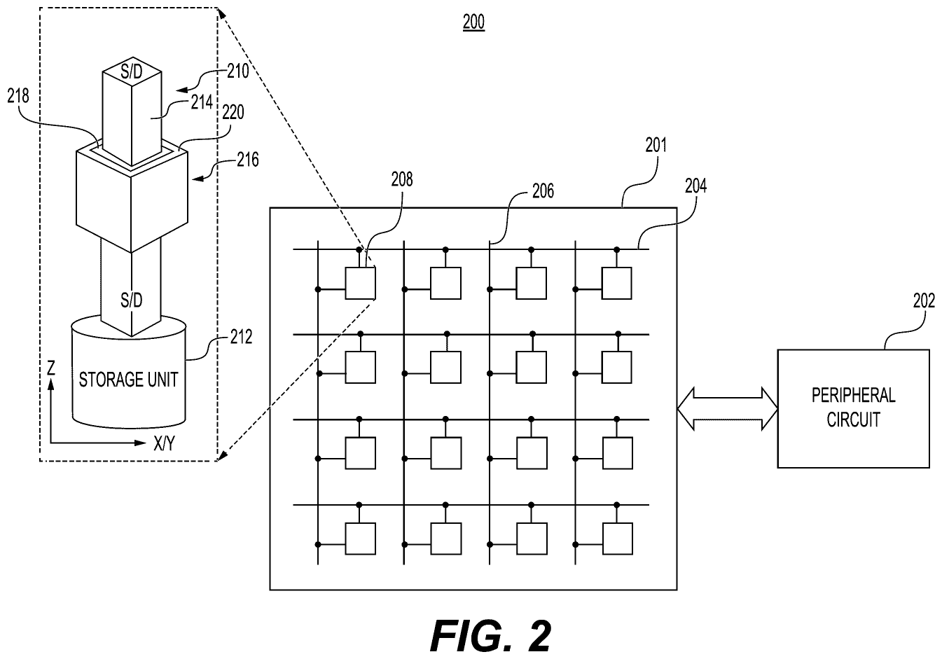

FIG. 2 illustrates a schematic diagram of a memory device 200 including peripheral circuits and an array of memory cells each having a vertical transistor, according to some aspects of the present disclosure. Memory device 200 can include a memory cell array 201 and peripheral circuits 202 coupled to memory cell array 201. Memory cell array 201 can be any suitable memory cell array in which each memory cell 208 includes a vertical transistor 210 and a storage unit 212 coupled to vertical transistor 210. In some implementations, memory cell array 201 is a DRAM cell array, and storage unit 212 is a capacitor for storing charge as the binary information stored by the respective DRAM cell. In some implementations, memory cell array 201 is a PCM cell array, and storage unit 212 is a PCM element (e.g., including chalcogenide alloys) for storing binary information of the respective PCM cell based on the different resistivities of the PCM element in the amorphous phase and the crystalline phase. In some implementations, memory cell array 201 is a FRAM cell array, and storage unit 212 is a ferroelectric capacitor for storing binary information of the respective FRAM cell based on the switch between two polarization states of ferroelectric materials under an external electric field.

As shown in FIG. 2, memory cells 208 can be arranged in a two-dimensional (2D) array having rows and columns. Memory device 200 can include word lines 204 coupling peripheral circuits 202 and memory cell array 201 for controlling the switch of vertical transistors 210 in memory cells 208 located in a row, as well as bit lines 206 coupling peripheral circuits 202 and memory cell array 201 for sending data to and/or receiving data from memory cells 208 located in a column. That is, each word line 204 is coupled to a respective row of memory cells 208, and each bit line is coupled to a respective column of memory cells 208.

Vertical transistors 210, such as vertical metal-oxide-semiconductor field-effect transistors (MOSFETs), can replace the planar transistors as the pass transistors of memory cells 208 to reduce the area occupied by the pass transistors, the coupling capacitance, as well as the interconnect routing complexity. As shown in FIG. 2, in some implementations, different from planar transistors in which the active regions are formed in the substrates, vertical transistor 210 includes a semiconductor body 214 extending vertically (in the z-direction) above the substrate (not shown). That is, semiconductor body 214 can extend above the top surface of the substrate to allow channels to be formed not only at the top surface of semiconductor body 214, but also at one or more side surfaces thereof.

As shown in FIG. 2, for example, semiconductor body 214 can have a cuboid shape to expose four sides thereof. It is understood that semiconductor body 214 may have any suitable 3D shape, such as a polyhedron shape or a cylinder shape. That is, the cross-section of semiconductor body 214 in the plan view (e.g., in the x-y plane) can have a square shape, a rectangular shape (or a trapezoidal shape), a circular (or an oval shape), or any other suitable shapes. It is understood that, for semiconductor bodies that have a circular or oval shape of their cross-sections in the plan view, the semiconductor bodies may still be considered as having multiple sides, such that the gate structures are in contact with more than one side of the semiconductor bodies. As described below with respect to the fabrication process, in some cases, semiconductor body 214 can be formed from the substrate (e.g., by etching or epitaxy) and thus, has the same semiconductor material (e.g., silicon crystalline silicon) as the substrate (e.g., a silicon substrate).

As shown in FIG. 2 example, vertical transistor 210 can also include a gate structure 216 in contact with one or more sides of semiconductor body 214, e.g., in one or more planes of the side surface(s) of the active region. In other words, the active region of vertical transistor 210, e.g., semiconductor body 214, can be at least partially surrounded by gate structure 216. Gate structure 216 can include a gate dielectric 218 over one or more sides of semiconductor body 214, e.g., in contact with four side surfaces of semiconductor body 214 as shown in FIG. 2. Gate structure 216 can also include a gate electrode 220 over and in contact with gate dielectric 218. Gate dielectric 218 can include any suitable dielectric materials, such as silicon oxide, silicon nitride, silicon oxynitride, or high-k dielectrics. For example, gate dielectric 218 may include silicon oxide, which is a form of gate oxide. Gate electrode 220 can include any suitable conductive materials, such as polysilicon, metals (e.g., tungsten (W), copper (Cu), aluminum (Al), etc.), metal compounds (e.g., titanium nitride (TiN), tantalum nitride (TaN), etc.), or silicides. For example, gate electrode 220 may include doped polysilicon, which is a form of a gate poly. In some implementations, gate electrode 220 includes multiple conductive layers, such as a W layer over a TiN layer. It is understood that gate electrode 220 and word line 204 may be a continuous conductive structure in some examples. In other words, gate electrode 220 may be viewed as part of word line 204 that forms gate structure 216, or word line 204 may be viewed as the extension of gate electrode 220 to be coupled to peripheral circuits 202.

As shown in FIG. 2, vertical transistor 210 can further include a pair of a source and a drain (S/D, dope regions, a.k.a., source electrode and drain electrode) formed at the two ends of semiconductor body 214 in the vertical direction (the z-direction), respectively. The source and drain can be doped with any suitable P-type dopants, such as boron (B) or Gallium (Ga), or any suitable N-type dopants, such as phosphorus (P) or arsenic (As). The source and drain can be separated by gate structure 216 in the vertical direction (the z-direction). In other words, gate structure 216 is formed vertically between the source and drain. As a result, one or more channels (not shown) of vertical transistor 210 can be formed in semiconductor body 214 vertically between the source and drain when a gate voltage applied to gate electrode 220 of gate structure 216 is above the threshold voltage of vertical transistor 210. That is, each channel of vertical transistors 210 is also formed in the vertical direction along which semiconductor body 214 extends, according to some implementations.

In some implementations, as shown in FIG. 2, vertical transistor 210 is a multi-gate transistor. That is, gate structure 216 can be in contact with more than one side of semiconductor body 214 (e.g., four sides in FIG. 2) to form more than one gate, such that more than one channel can be formed between the source and drain in operation. That is, different from the planar transistor that includes only a single planar gate (and resulting in a single planar channel), vertical transistor 210 shown in FIG. 2 can include multiple vertical gates on multiple sides of semiconductor body 214 due to the 3D structure of semiconductor body 214 and gate structure 216 that surrounds the multiple sides of semiconductor body 214. As a result, compared with planar transistors, vertical transistor 210 shown in FIG. 2 can have a larger gate control area to achieve better channel control with a smaller subthreshold swing. Since the channel is fully depleted, the leakage current (Ioff) of vertical transistor 210 can be significantly reduced a well. In various examples, the multi-gate vertical transistors can include double-gate vertical transistors (e.g., dual-side gate vertical transistors), tri-gate vertical transistors (e.g., tri-side gate vertical transistors), and GAA vertical transistors.

It is understood that although vertical transistor 210 is shown as a multi-gate transistor in FIG. 2, the vertical transistors disclosed herein may also include single-gate transistors. That is, gate structure 216 may be in contact with a single side of semiconductor body 214, for example, for the purpose of increasing the transistor and memory cell density. It is also understood that although gate dielectric 218 is shown as being separate (a separate structure) from other gate dielectrics of adjacent vertical transistors (not shown), gate dielectric 218 may be part of a continuous dielectric layer having multiple gate dielectrics of vertical transistors.

In planar transistors and some lateral multiple-gate transistors (e.g., FinFET), the active regions, such as semiconductor bodies (e.g., Fins), extend laterally (in the x-y plane), and the source and the drain are disposed at different locations in the same lateral plane (the x-y plane). In contrast, in vertical transistor 210, semiconductor body 214 extends vertically (in the z-direction), and the source and the drain are disposed in the different lateral planes, according to some implementations. In some implementations, the source and the drain are formed at two ends of the semiconductor body 214 in the vertical direction (the z-direction), respectively, thereby being overlapped in the plan view. As a result, the area (in the x-y plane) occupied by vertical transistor 210 can be reduced compared with planar transistors and lateral multiple-gate transistors. Also, the metal wiring coupled to vertical transistors 210 can be simplified as well since the interconnects can be routed in different planes. For example, bit lines 206 and storage units 212 may be formed on opposite sides of vertical transistor 210. In one example, bit line 206 may be coupled to the source or the drain at the upper end of semiconductor body 214, while storage unit 212 may be coupled to the other source or the drain at the lower end of semiconductor body 214.

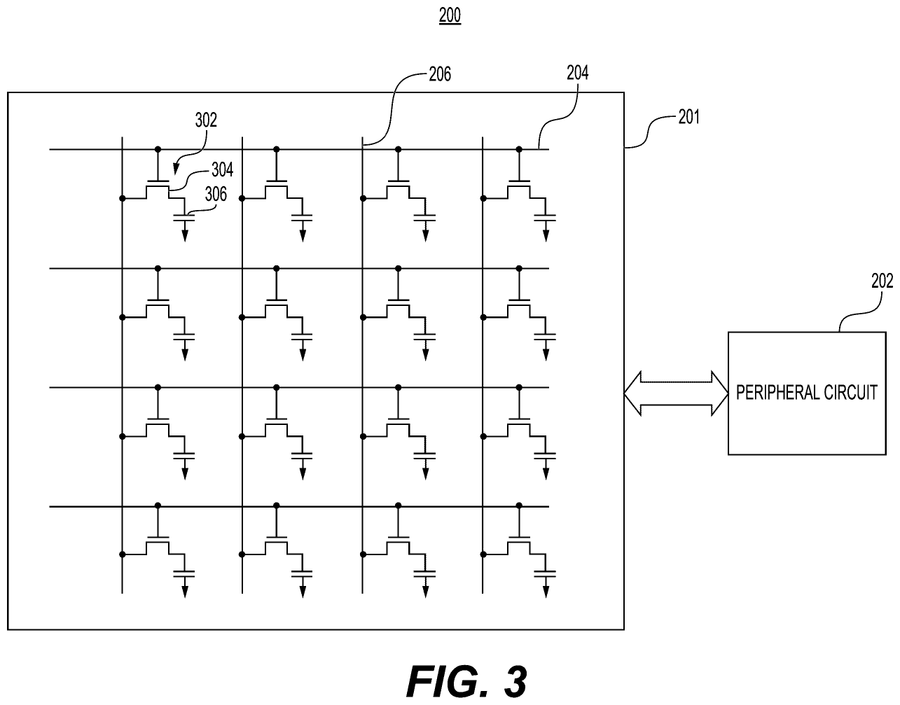

As shown in FIG. 2, storage unit 212 can be coupled to the source or the drain of vertical transistor 210. Storage unit 212 can include any devices that are capable of storing binary data (e.g., 0 and 1), including but not limited to, capacitors for DRAM cells and FRAM cells, and PCM elements for PCM cells. In some implementations, vertical transistor 210 controls the selection and/or the state switch of the respective storage unit 212 coupled to vertical transistor 210. In some implementations, as shown in FIG. 3, each memory cell 208 is a DRAM cell 302 including a transistor 304 (e.g., implementing using vertical transistors 210 in FIG. 2) and a capacitor 306 (e.g., an example of storage unit 212 in FIG. 2). The gate of transistor 304 (e.g., corresponding to gate electrode 220) may be coupled to word line 204, one of the source and the drain of transistor 304 may be coupled to bit line 206, the other one of the source and the drain of transistor 304 may be coupled to one electrode of capacitor 306, and the other electrode of capacitor 306 may be coupled to the ground.

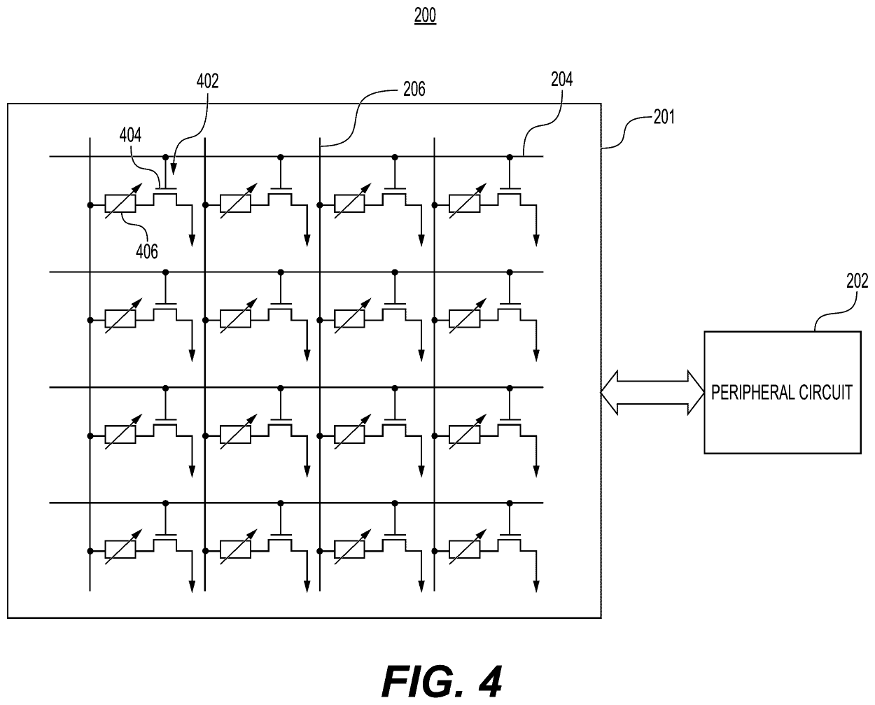

In some implementations, as shown in FIG. 4, each memory cell 208 is a PCM cell 402 including a transistor 404 (e.g., implementing using vertical transistors 210 in FIG. 2) and a PCM clement 406 (e.g., an example of storage unit 212 in FIG. 2). The gate of transistor 404 (e.g., corresponding to gate electrode 220) may be coupled to word line 204, one of the source and the drain of transistor 404 may be coupled to the ground, the other one of the source and the drain of transistor 404 may be coupled to one electrode of PCM element 406, and the other electrode of PCM element 406 may be coupled to bit line 206.

Peripheral circuits 202 can be coupled to memory cell array 201 through bit lines 206, word lines 204, and any other suitable metal wirings. As described above, peripheral circuits 202 can include any suitable circuits for facilitating the operations of memory cell array 201 by applying and sensing voltage signals and/or current signals through word lines 204 and bit lines 206 to and from each memory cell 208. For example, peripheral circuits 202 can include various types of peripheral circuits formed using CMOS technologies.

### II. Fabrication Process to Protect Word Line in Backside Process

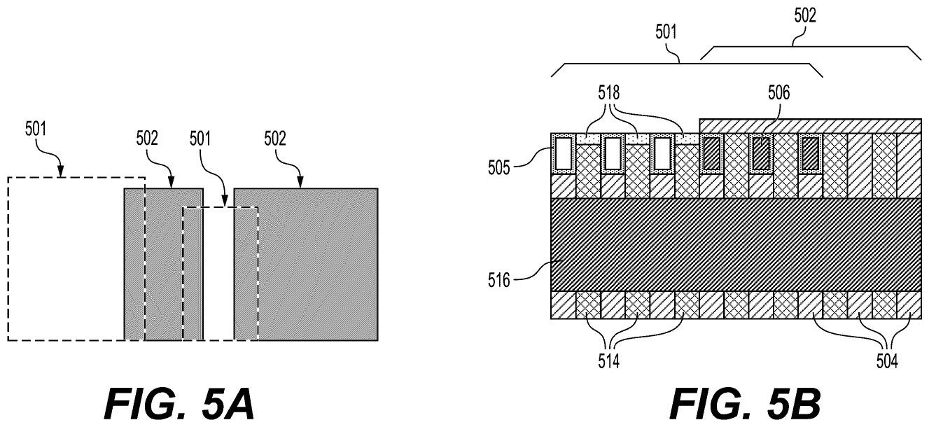

FIGS. 5A-5B illustrate a result of a fabrication process where trench recess regions overlap insulating layers for bit line formation at a backside of a semiconductor device. FIG. 5A illustrates the top-view of the overlapped trench recess regions and insulating layers. FIG. 5B illustrates a cross-section view of the semiconductor device along the word line direction. During the fabrication process, at the backside of the semiconductor device, the trench recess region 501 can be defined to recess the trench isolations 504 and gate structures (word lines 516) along the bit line direction. A spacer 505 can be deposited to cover the surface of the space resulting from the recess. The space can later be filled with a sacrificial material 506. The spacer 505 can be any suitable dielectric materials, such as silicon nitride, silicon oxide, silicon oxynitride, or high-k dielectrics. The sacrificial material 506 can be any suitable conductive or non-conductive materials, such as polysilicon, metals (e.g., tungsten (W), copper (Cu), aluminum (Al), etc.), metal compounds (e.g., titanium nitride (TiN), tantalum nitride (TaN), etc.), or silicides.

Insulating layer 502 can then be formed at the backside of the semiconductor device. As shown in FIG. 5A and 5B, the insulating layer 502 covers a portion of the trench recess region 501 resulting in an overlap between the insulating layer 502 and the trench recess region 501. The sacrificial materials 506 that are not covered by the insulating layer 502 are removed by performing an etch process to form air gaps between semiconductor bodies 514. Bit lines 518 can then be formed on top of the semiconductor bodies 514 along the bit line direction in the trench recess region 501 that are not covered by the insulating layer 502. However, due to the insulating layer 502, the sacrificial materials 506 covered by the insulating layer 502 are not removed. The existing of the sacrificial materials 506 can potentially cause current leakage. It is desirable to completely remove the sacrificial materials 506 under the insulating layer 502.

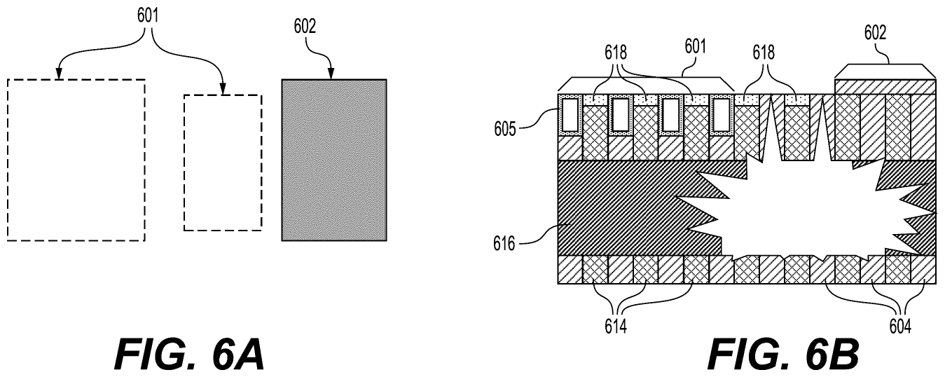

FIGS. 6A-6B illustrate a result of a fabrication process where trench recess regions and insulating layers for bit line formation are not overlapped with each other at a backside of the semiconductor device. FIG. 6A illustrates the top-view of the non-overlapped trench recess regions and insulating layers. FIG. 6B illustrates a cross-section view of the semiconductor device along the word line direction. At the backside of the semiconductor device, the trench recess region 601 can be defined to recess the trench isolations 604 and gate structures 616 along the bit line direction. Similarly, after deposition of a spacer 605, the space resulting from the recess can then be filled with a sacrificial material 606. The spacer 605 can be any suitable dielectric materials, such as silicon nitride, silicon oxide, silicon oxynitride, or high-k dielectrics. The sacrificial material 606 can be any suitable conductive materials, such as polysilicon, metals (e.g., tungsten (W), copper (Cu), aluminum (Al), etc.), metal compounds (e.g., titanium nitride (TiN), tantalum nitride (TaN), etc.), or silicides.

Insulating layer 602 can then be formed at the backside of the semiconductor device. As shown in FIG. 6A and 6B, the insulating layer 602 and the trench recess region 601 do not overlap, resulting in a few trench isolations 604 and semiconductor bodies 614 not covered by any of the insulating layer 602 and trench recess region 601. The sacrificial materials 606 are removed by performing an etch process, to form air gaps between semiconductor bodies 614. Bit lines 618 can then be formed on semiconductor bodies 614 along the bit line direction that are not covered by the insulating layer 602. Due to the difficulty of controlling a uniform depth of trenches for the gate structures in the semiconductor device with a vertical all in one etch process, certain gate structures 616 may have abnormal heights when viewed from the backside of the semiconductor device. During the removal process of the sacrificial materials 606, gate structures 616 with abnormal heights that are not covered by the trench recess regions 601 and not covered by the insulating layers 602 may also be removed together from the backside of the semiconductor device, which may result in word line missing (or broken) as shown in FIG. 6B. To mitigate this word line broken issue, the current disclosure provides a backside processing method where the insulating layer 602 is disposed to overlap the trench recess region 601, reducing or eliminating the chance of accidentally etching the word lines. At the same, a tunnel structure crossing below bit lines is employed to remove the sacrificial materials 506 under the insulating layer 502 (as shown in FIG. 5B), which can solve the leakage issue.

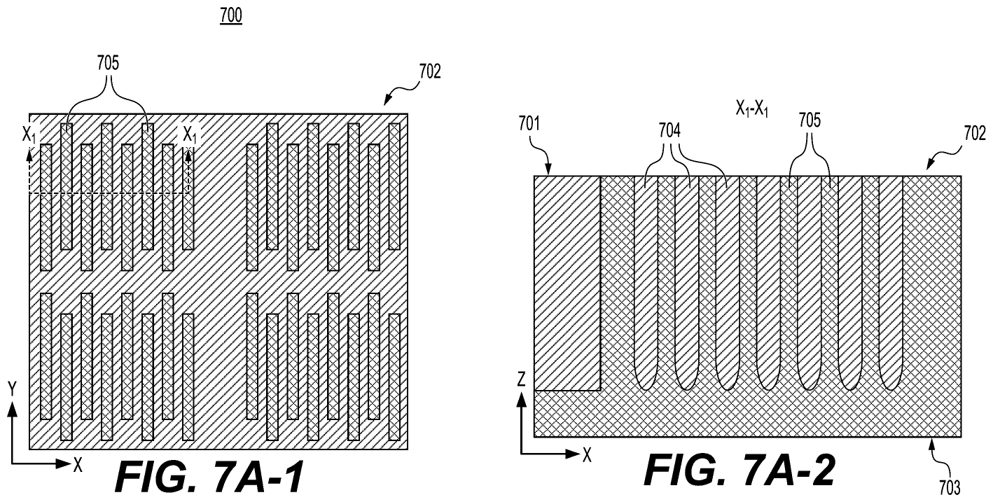

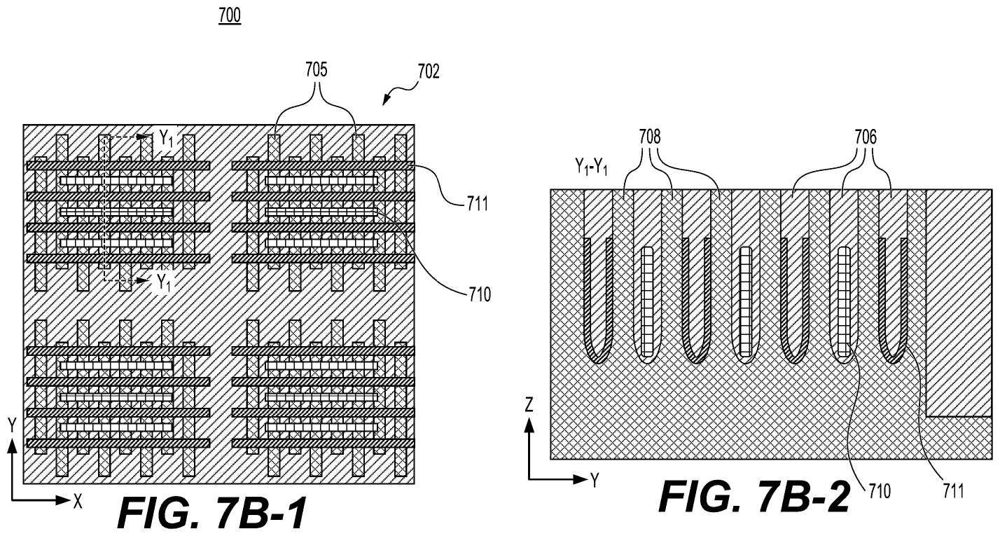

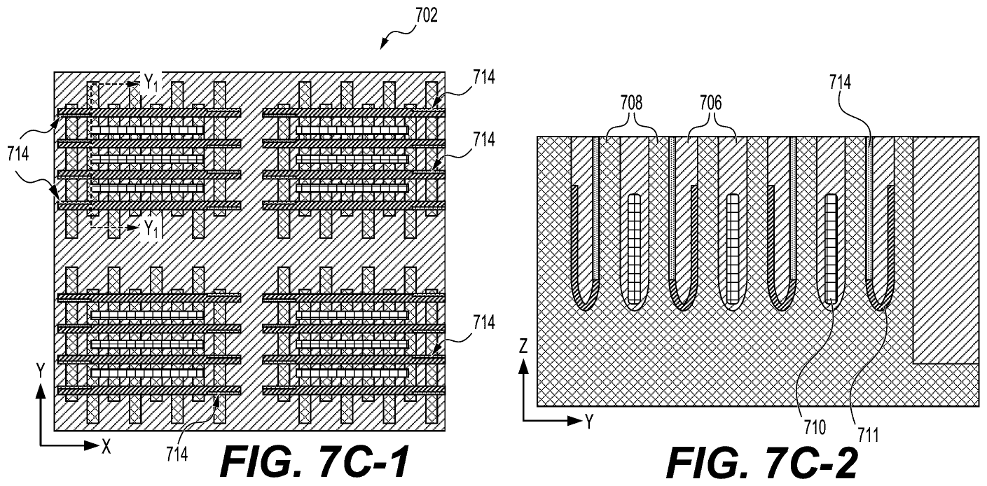

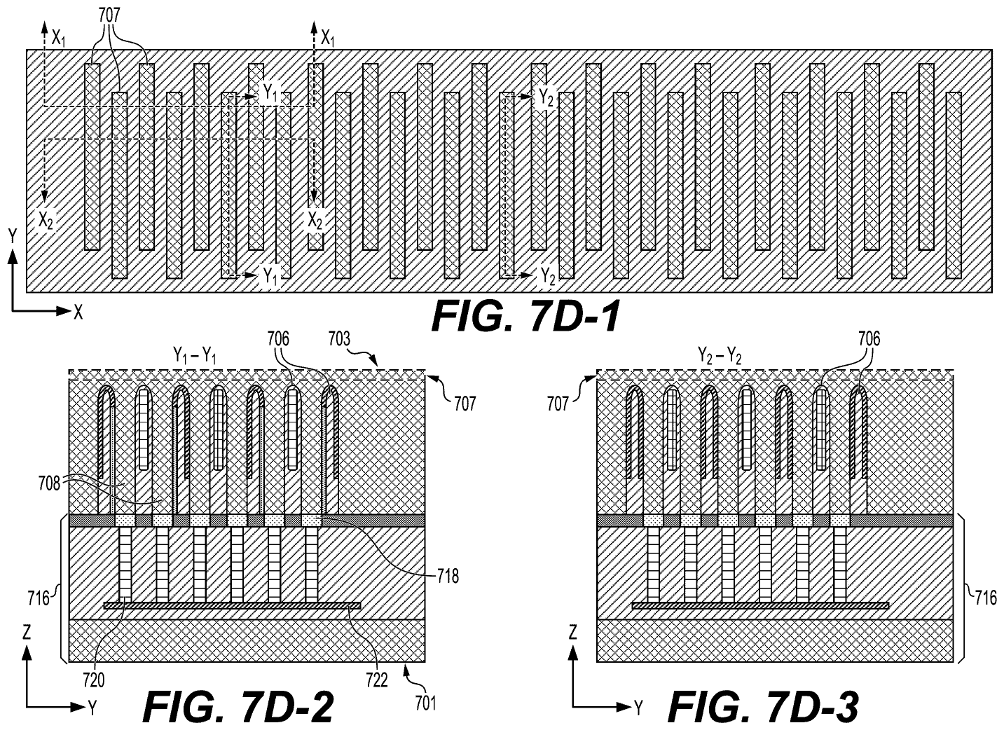

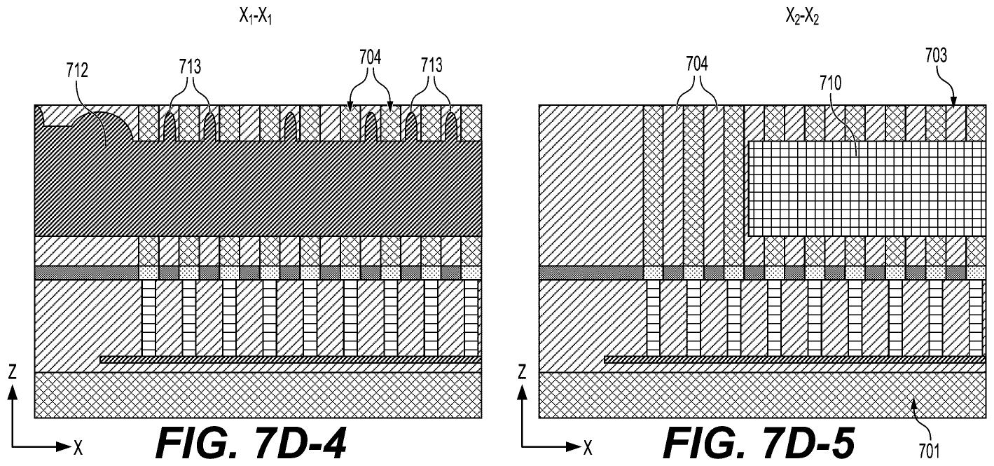

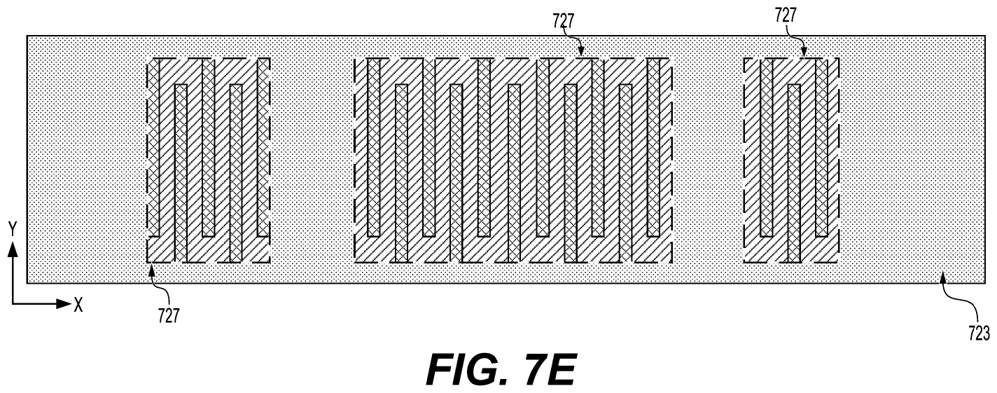

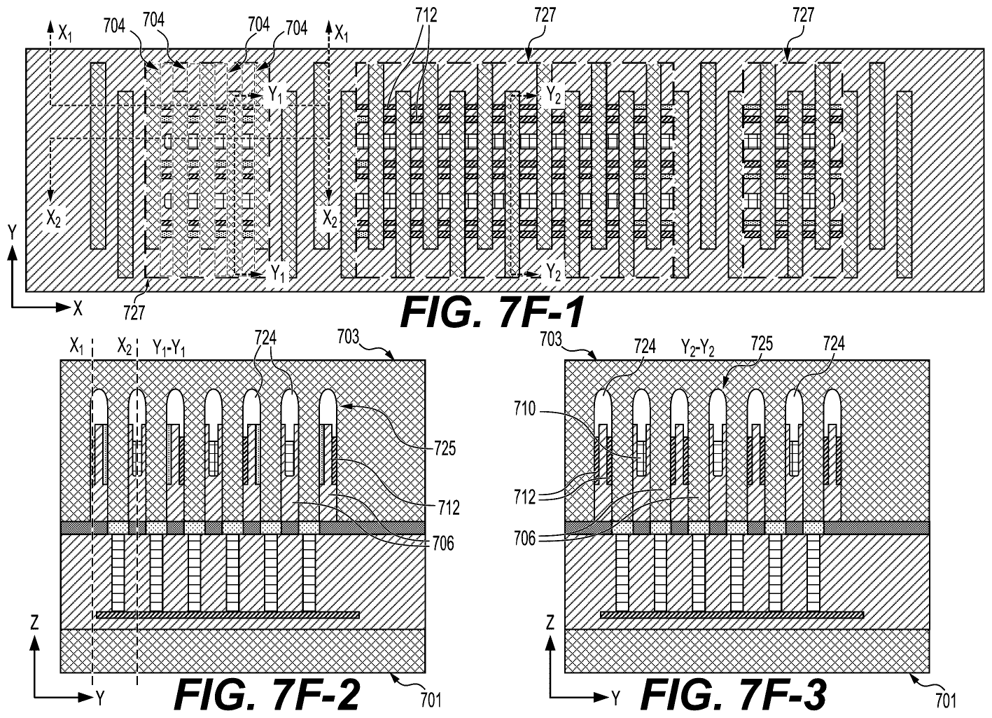

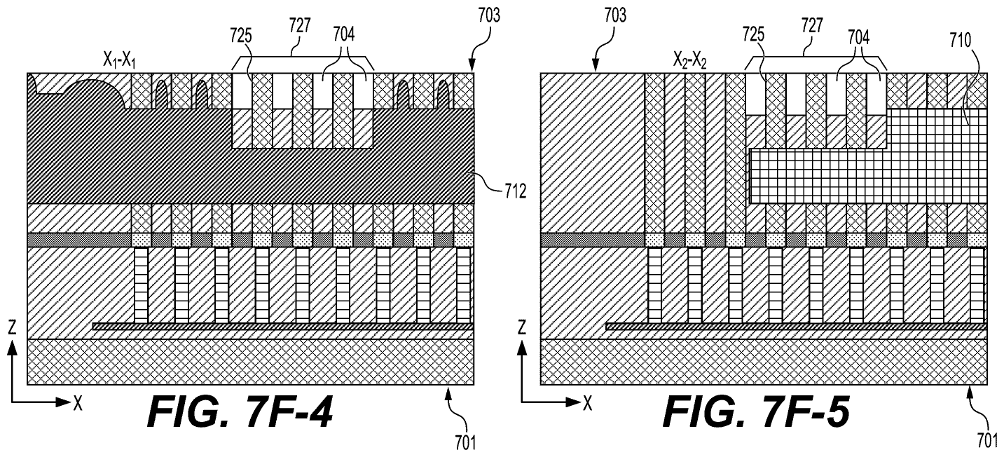

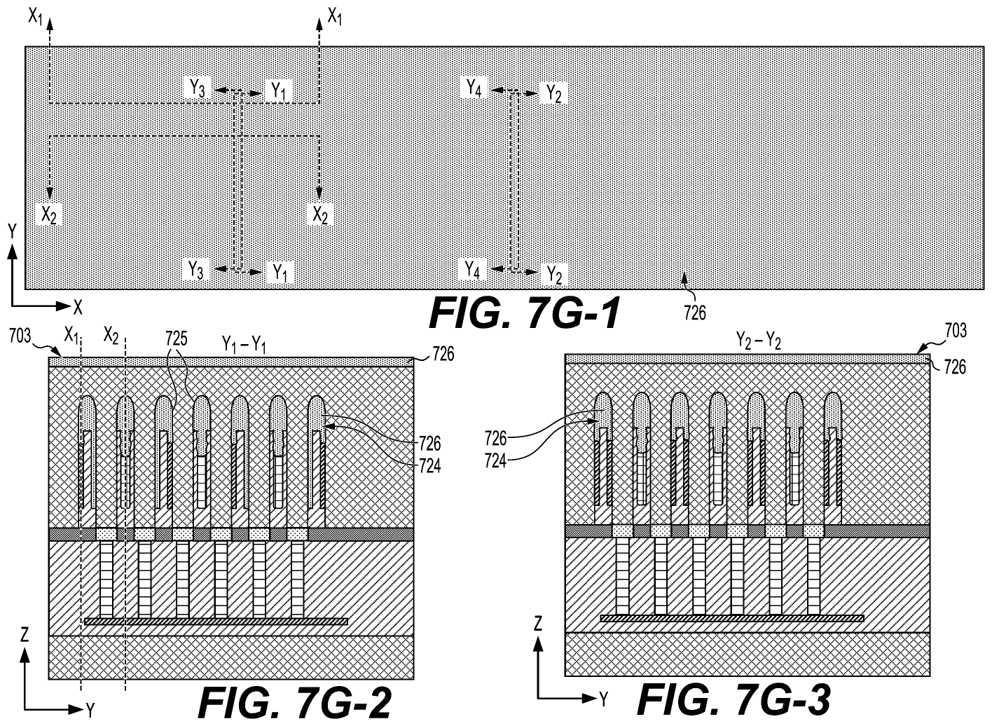

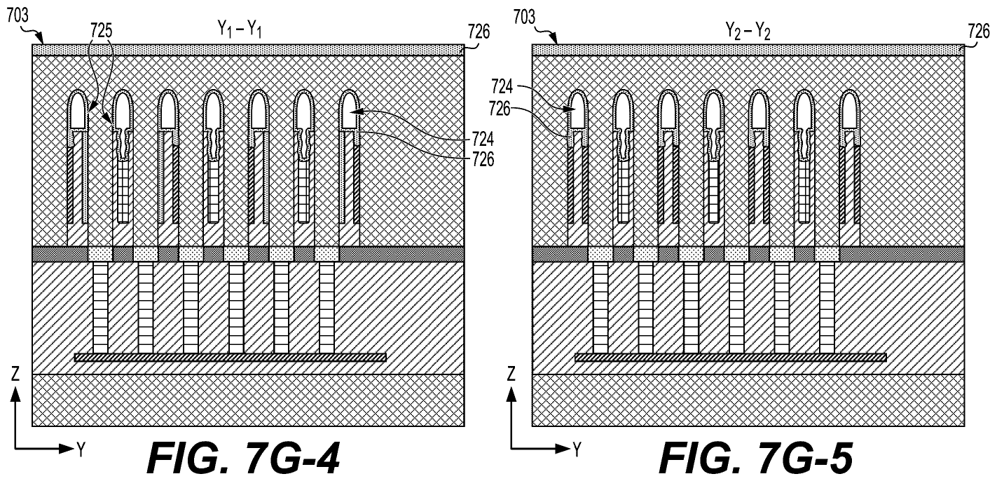

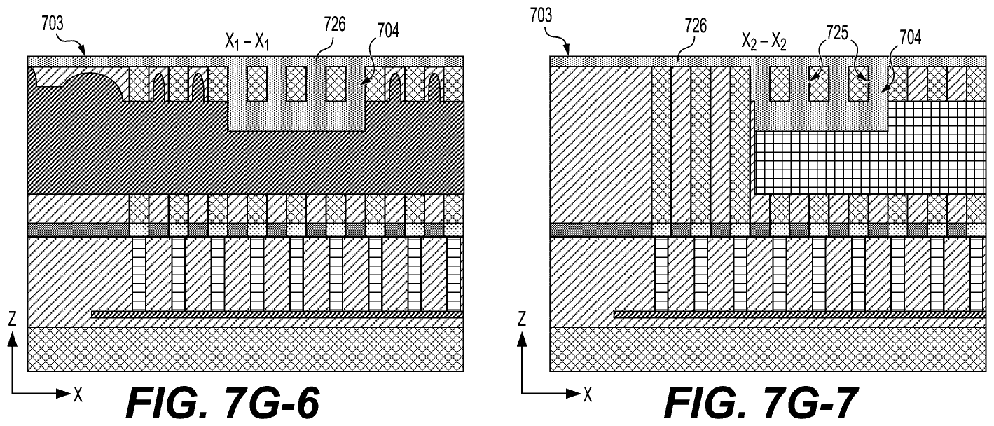

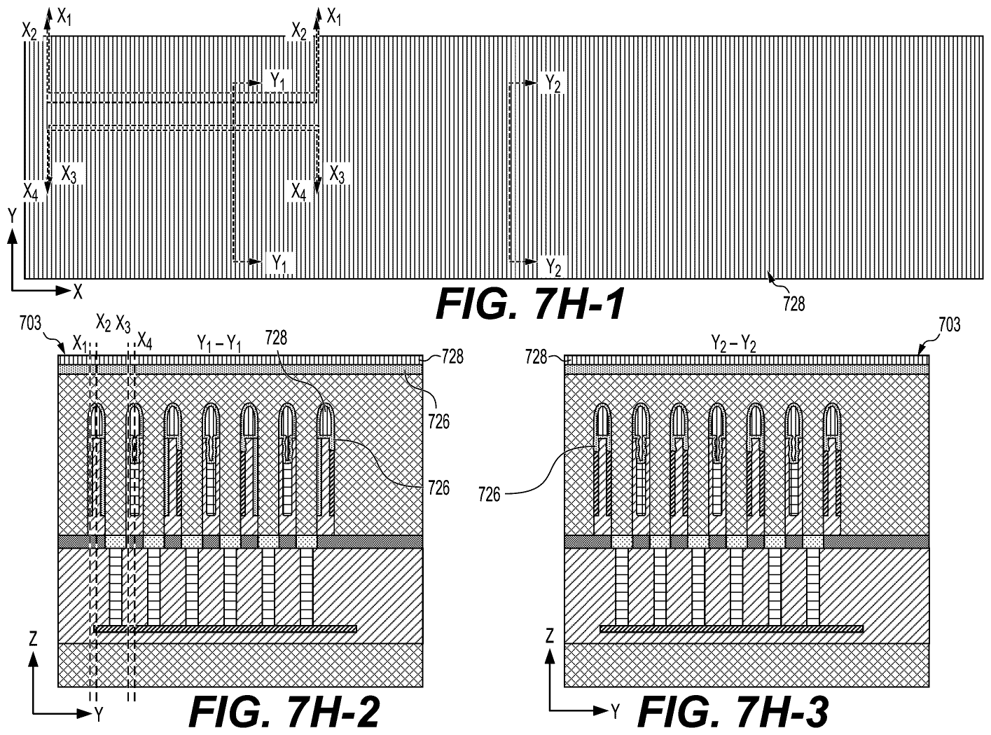

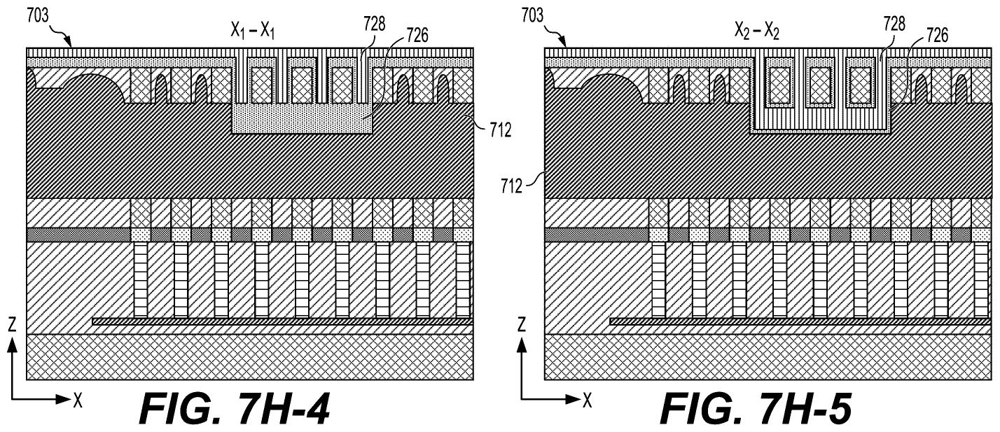

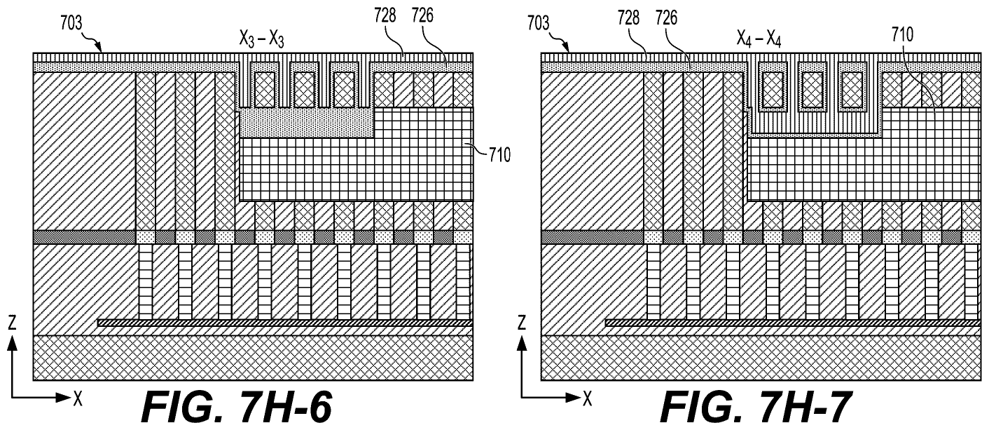

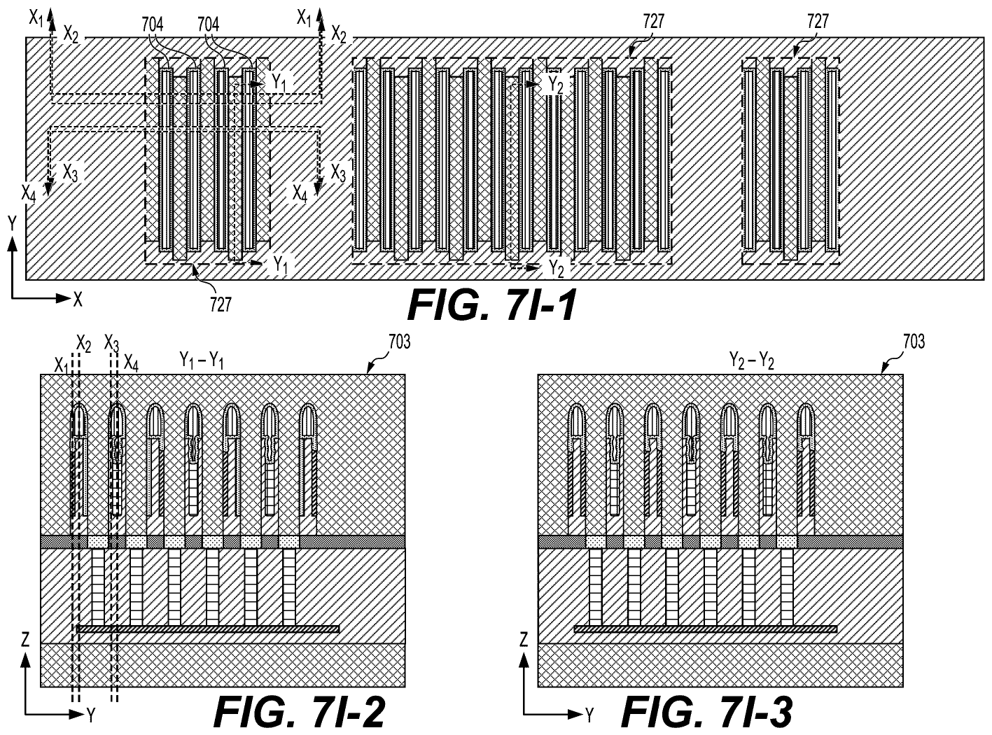

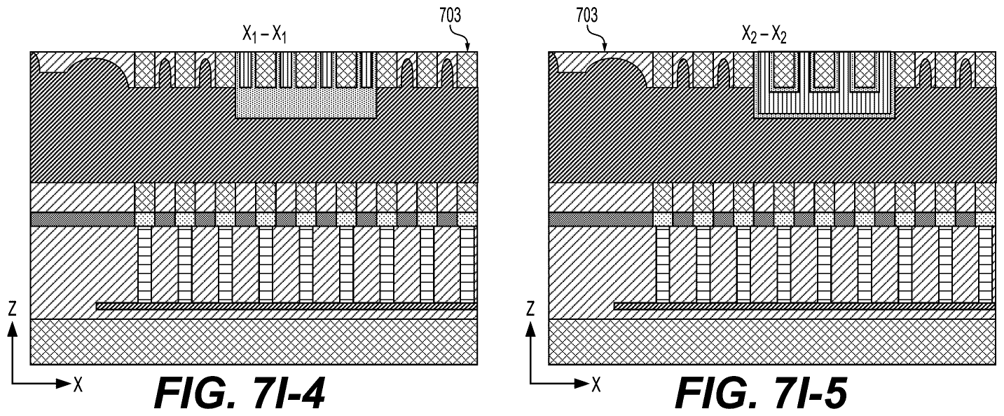

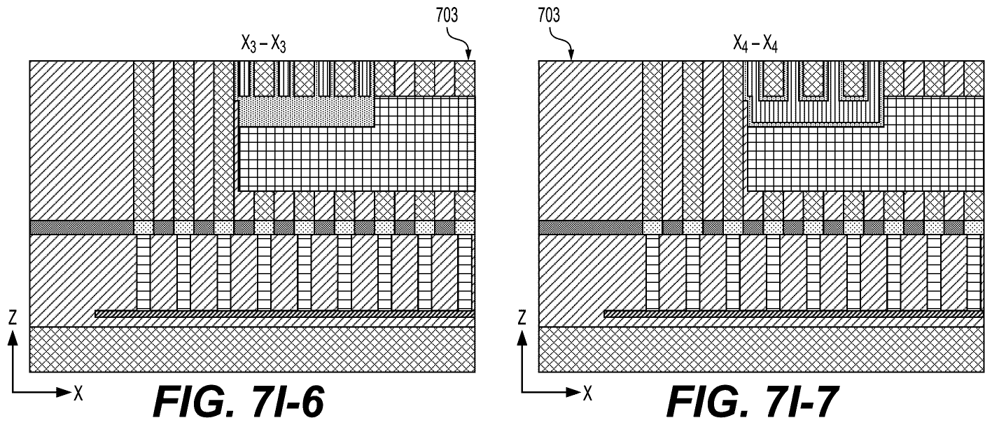

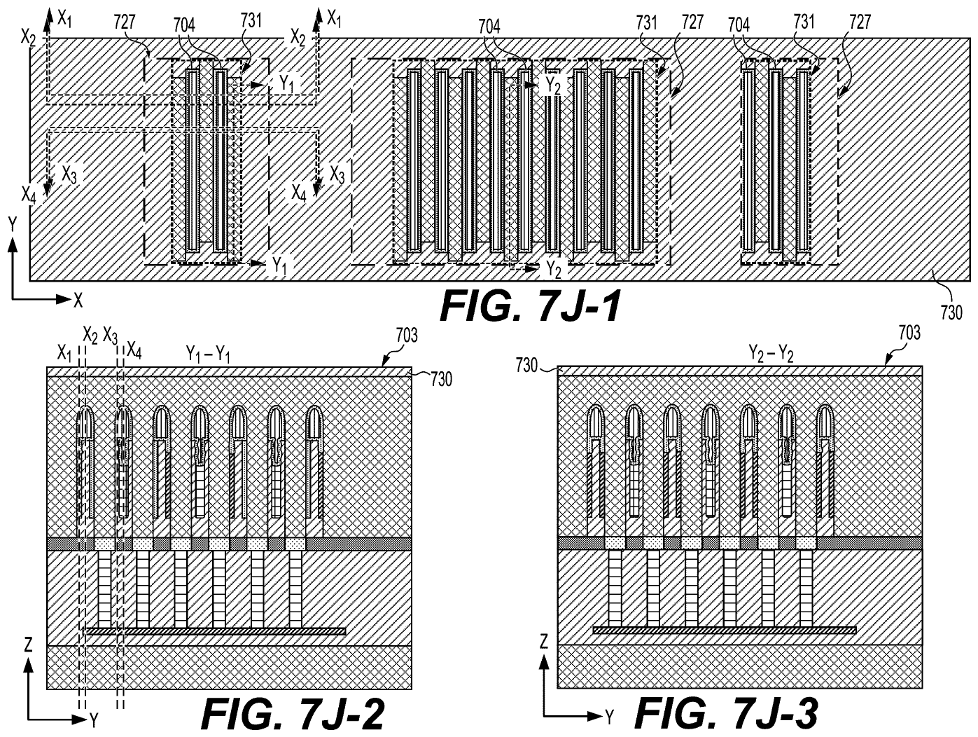

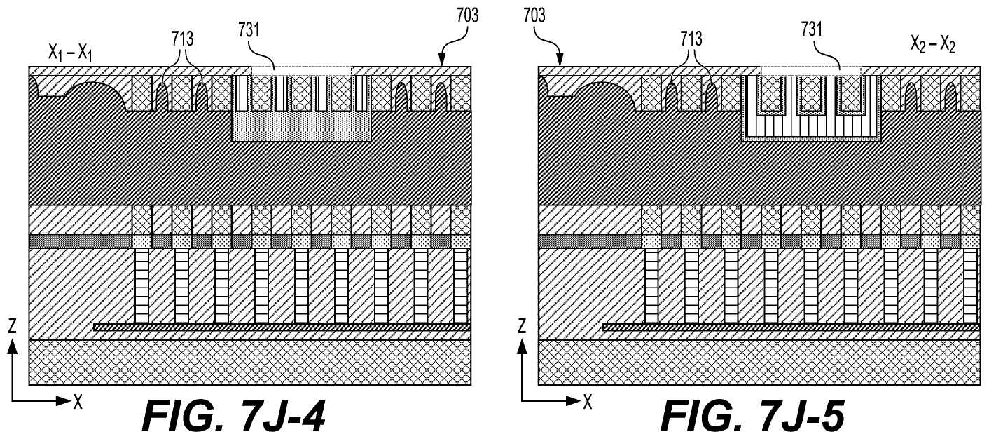

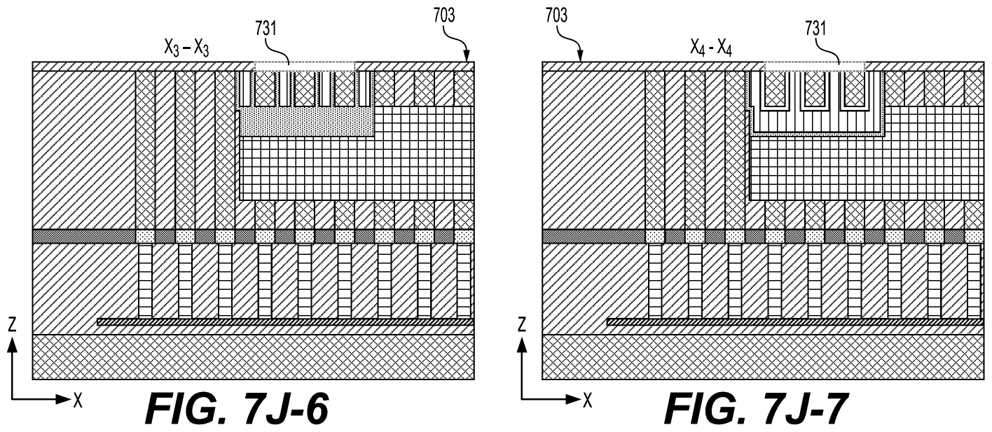

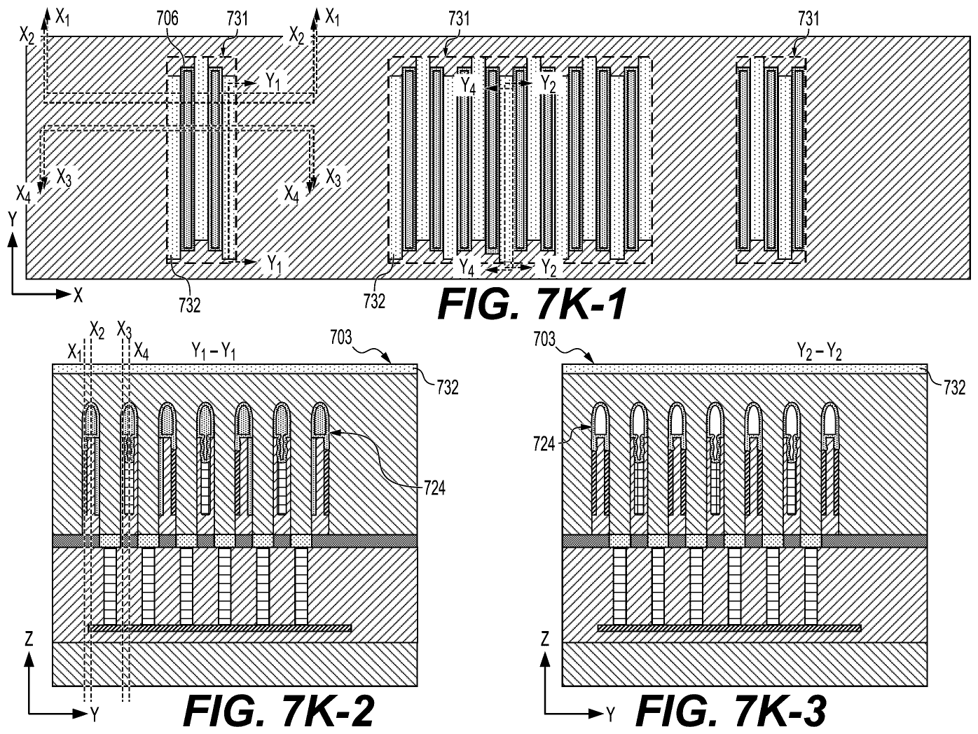

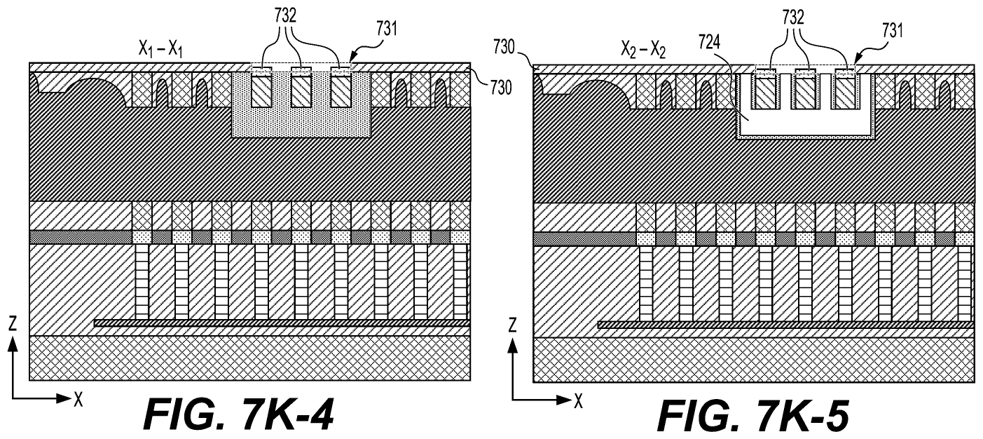

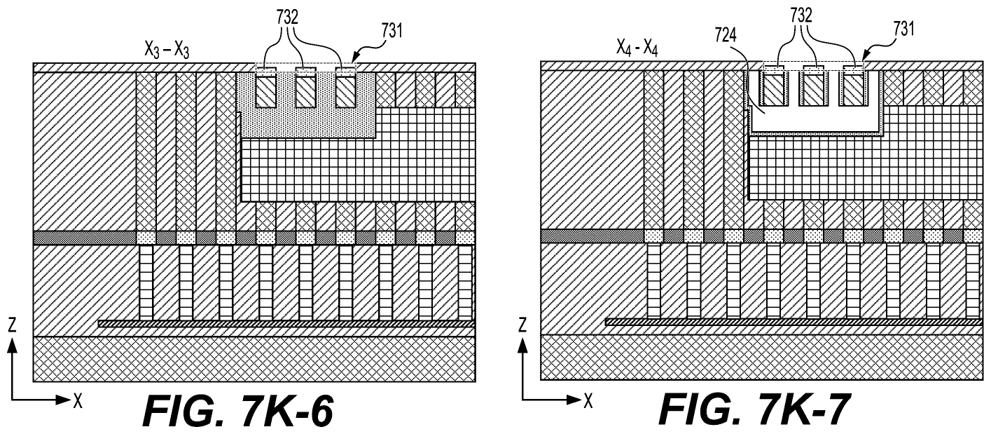

FIGS. 7A-1˜7A-2/7B-1˜7B-2/7C-1˜7C-2/7D-1˜7D-5/7E/7F-1˜7F-5/7G-1˜7G-7/7H-1˜7H-7/7I-1˜7I-7/7J-1˜7J-7/7K-1˜7K-7 illustrate a fabrication process for forming a memory device according to some aspects of the present disclosure.

FIG. 7A-1 illustrates a plan view of a semiconductor memory device 700 having four sections from a topside 701. FIGS. 7A-2 illustrates a partial section view corresponding to the cut line X1-X1. In FIGS. 7A-1/7A-2, trench isolations 704 (e.g., STIs) are formed in a semiconductor substrate 702 of a semiconductor memory device 700 in a bit line direction (e.g., y direction). The semiconductor substrate 702 can be a silicon substrate. The semiconductor memory device 700 (as well as the semiconductor substrate 702) can have the topside 701 and a backside 703. The trench isolations 704 are formed from the topside 701. In some implementations, a lithography process is performed to pattern trenches and semiconductor walls 705 in the semiconductor substrate 702 using an etch mask (e.g., a photoresist mask and/or a hard mask), for example, based on the design of bit lines. One or more dry etching and/or wet etching processes, such as reactive ion etch (RIE), are performed on the semiconductor substrate 702. In some implementations, a dielectric, such as silicon oxide, is deposited to fully fill the trenches to form trench isolations 704 using one or more thin film deposition processes including, but not limited to, CVD, PVD, ALD, or any combination thereof. In some implementations, a planarization process, such as CMP, is performed to remove excess dielectric deposited beyond the top surface of the topside 701.

FIG. 7B-1 illustrates a plan view of the semiconductor memory device 700 having four sections from the topside 701. FIGS. 7B-2 illustrates a partial section view corresponding to the cut line Y1-Y1. In FIGS. 7B-1/7B-2, word line trenches 706 are formed along the word line direction (e.g., x direction). In some implementations, a lithography process is performed to pattern word line trenches 706 to be perpendicular to trench isolations 704 using an etch mask (e.g., a photoresist mask and/or a hard mask), for example, based on the design of word lines. One or more dry etching and/or wet etching processes, such as RIE, are performed on semiconductor wall 705 and trench isolations 704 to etch word line trenches 706 in semiconductor substrate 702. As a result, semiconductor bodies 708 are formed as the result of forming the word line trenches 706 and the trench isolations 704. The semiconductor bodies 708 can extend in a vertical direction (e.g., z direction). Word line layers 711 can be formed in the word line trenches 706 along the sidewalls of semiconductor bodies 708 and connect to the sidewalls of semiconductor bodies 708 in a row. The word line layers 711 includes word lines and gate structures (not shown) of the semiconductor bodies 708 can be formed in a similar manner as described in FIG. 2 above. At this stage, the word line layers 711 are connected at the bottom of each corresponding word line trench 706. Word lines connect rows of the semiconductor bodies 708 are formed in a later process discussed below. Metal shields 710 can be formed in the word line trenches 706 and between two neighboring word line layers 711 in a similar process as forming the word lines. The word line trenches 706 can then be filled with an insulating material, such as silicon oxide.

FIG. 7C-1 illustrates a plan view of the semiconductor memory device 700 having four sections from the topside 701. FIGS. 7C-2 illustrates a partial section view corresponding to the cut line Y1-Y1. In FIGS. 7C-1/7C-2, portions 714 of word line layers 711 are recessed down from the topside 701 at desired locations. Each word line layer 711 has two portions 714 being recessed down to form two separated word lines that disconnect at the recessed region. That is, each row of the semiconductor body 708 along the word line direction (x direction) is in contact with only one word line. At this stage, the word line layer 711 within each word line trench 704 includes two separated word lines that are still connected at the bottom of each word line trench 704. The bottom connected portion will be disconnected in a backside process detailed below. In some implementations, a lithography process is performed to pattern the portions 714 using an etch mask (e.g., a photoresist mask and/or a hard mask), for example, based on the design of word lines. One or more dry etching and/or wet etching processes, such as reactive ion etch (RIE), can be performed to etch and recess the word line layers 711. In some implementations, the portions 714 of word line layers 711 being recessed are located close to ends of each word line trenches 706 and within trench isolations 704 to maximize the number of semiconductor bodies 708 connected in one row by one word line. The portions 714 can then be filled with insulating materials, such as silicon nitride.

FIG. 7D-1 illustrates an enlarged plan view of one of the sections of the semiconductor memory device 700 from the backside 703. FIGS. 7D-2 and 7D-3 illustrate partial section views corresponding to cut line Y1-Y1 and cut line Y2-Y2 respectively. FIGS. 7D-4 and 7D-5 illustrate partial section views corresponding to cut line Y1-Y1 and cut line Y2-Y2 respectively. In FIGS. 7D-1/7D-2/7D-3/7D-4/7D-5, the semiconductor substrate 702 is thinned from the backside 703 after storage units 720 are formed on respective semiconductor bodies 708. Upper ends of the semiconductor bodies 708 at the topside 701 can be doped. The exposed end of each semiconductor body 708 is doped to form a source/drain (e.g., a source terminal of a vertical transistor). In some implementations, an implantation process and/or thermal diffusion process are performed to dope P-type dopants or N-type dopants to exposed upper ends of semiconductor bodies 708 to form sources/drains. In some implementations, a silicide layer is formed on source/drain by performing a silicidation process at the exposed upper ends of semiconductor bodies 708.

Storage units in contact with the semiconductor bodies, e.g., the doped first ends thereof, are formed. The storage unit can include a capacitor or a PCM element. In some implementations, to form a storage unit that is a capacitor, a first electrode is formed on the doped upper end of the semiconductor body, a capacitor dielectric is formed on the first electrode, and a second electrode is formed on the capacitor dielectric.

For example, one or more interlayer dielectric (ILD) layers 716 are formed over the topside 701, for example, by depositing dielectrics using one or more thin film deposition processes including, but not limited to, CVD, PVD, ALD, or any combination thereof. Storage unit contact (capacitor contact) 718, first electrodes, capacitor dielectrics, and second electrodes of storage units (capacitors) 720, and a common plate 722 are subsequently formed in the ILD layers 716 to be coupled to semiconductor bodies 708. In some implementations, capacitor contact 718 is formed on a respective source/drain, e.g., the doped upper end of a respective semiconductor body 708 by patterning and etching an electrode hole aligned with the respective source/drain using lithography and etching processes and depositing conductive materials to fill the electrode hole using thin film deposition processes. In some implementations, common plate 722 is formed on the second electrodes of capacitors 720 by patterning and etching an electrode trench aligned with capacitors 720 using lithography and etching processes and depositing conductive materials to fill the electrode trench using thin film deposition processes.

The semiconductor substrate 702 can be thinned at the backside 703 using CMP, grinding, dry etching, and/or wet etching. In some embodiments, the CMP process is performed to thin the semiconductor substrate 702 until reaching the trench isolations 704. After thinning the backside 703, trench isolations 704 are exposed. Lines of semiconductor structures 707 in the bit line direction (y direction) are exposed and connect columns of the semiconductor bodies 708 at the backside 703. The line of semiconductor structure 707 along with the respective columns of connected semiconductor bodies 708 forms a bridge-shaped structure, where the line of the semiconductor structure 707 is the beam and connected semiconductor bodies 708 are the piers. As illustrated in FIG. 7D-4, due to the difficulty in controlling a uniform depth of gate structures of the word line 712 with vertical all in one etch, the word line 712 may have abnormally higher regions 713 in the trench isolations 704.

FIG. 7E illustrates an enlarged plan view of one of the sections of the semiconductor memory device 700 from the backside 703. Trench recess regions 727 can be patterned out by applying a mask 723 at the backside 703. The locations of the trench recess regions 727 can be determined according to the functionalities of the specific design of the semiconductor memory device.

FIG. 7F-1 illustrates an enlarged plan view of one of the sections of the semiconductor memory device 700 from the backside 703. FIGS. 7F-2 and 7F-3 illustrate partial section views corresponding to cut line Y1-Y1 and cut line Y2-Y2 respectively. FIGS. 7F-4 and 7F-5 illustrate partial section views corresponding to cut line Y1-Y1 and cut line Y2-Y2 respectively. In FIGS. 7F-1/7F-2/7F-3/7F-4/7F-5, the trench isolations 704 within the trench recess regions 727 are recessed to expose the word line layers 711 and the metal shields 710. The word line layers 711 at the bottom of the word line trenches 706 are etched away to form two separated word lines 712 that each connects one row of semiconductor bodies 708. The word lines 712 and the metal shields 710 are further recessed down towards the topside 701 within the trench recess regions 727. FIG. 7F-4 illustrates the word line 712 that is further recessed towards the topside 701 within the trench recess region 727. FIG. 7F-5 illustrates the metal shield 710 that is further recessed towards the topside 701 within the trench recess region 727. One or more dry etching and/or wet etching processes, such as reactive ion etch (RIE), can be performed to etch and recess the trench isolations 704, word lines 712, and metal shields 710 within the trench recess regions 727.

Tunnels 724 are formed underneath the bridge-shaped structures along the bit line direction (y direction) within the trench recess regions 727. Tunnels 724 can have different shapes according to the respective word line 712 or metal shield 710. For example, as shown in FIG. 7F-2, tunnels 724 connected with the word lines 712 have a “P” shape, and tunnels 724 connected with the metal shields 710 have a “T” shape, as viewed at the Y1-Y1 cut line. For example, as shown in FIG. 7F-3, tunnels 724 connected with the word lines 712 have an “n” shape, as viewed at the Y2-Y2 cut line.

In some implementations, a lithography process can be performed to pattern the trench recess regions 727 by using an etch mask (e.g., a photoresist mask and/or a hard mask), for example, based on the design of bit lines. One or more dry etching and/or wet etching processes, such as RIE, can be performed on the semiconductor substrate 702 to etch away the trench isolations 704. After the trench isolations 704 are recessed, a second lithography process can be performed to pattern the word lines 712 and metal shields 710 within the trench recess regions 727. One or more dry etching and/or wet etching processes, such as RIE, can be performed to etch away the word lines 712 and metal shields 710 within the trench recess regions 727.

FIG. 7G-1 illustrates an enlarged plan view of one of the sections of the semiconductor memory device 700 from the backside 703. FIGS. 7G-2 and 7G-3 illustrate partial section views corresponding to the cut line Y1-Y1 and cut line Y2-Y2 respectively. FIG. 7G-4 illustrates a partial section view between cut lines Y1-Y1 and Y3-Y3. FIG. 7G-5 illustrates a partial section view between cut lines Y2-Y2 and Y4-Y4. FIGS. 7F-6 and 7F-7 illustrate partial section views corresponding to cut line Y1-Y1 and cut line Y2-Y2 respectively. In FIGS. 7G-1/7G-2/7G-3/7G-4/7G-5/7G-6/7G-7, a thin spacer layer 726 is deposited on the sidewalls 725 of the tunnels 724 and recessed trench isolations 704. As shown in FIGS. 7G-4 and 7G-5, the thin spacer layer 726 only formed on the sidewalls 725 of tunnels 724 and does not fill the tunnels 724 and the trench isolations 704. The thin spacer layer 726 is formed by depositing a layer of dielectric materials, such as silicon nitride, by using one or more thin film deposition processes including, but not limited to, CVD, PVD, ALD, or any combination thereof, without fully filling the trench isolations 704 and the tunnels 724.

FIG. 7H-1 illustrates an enlarged plan view of one of the sections of the semiconductor memory device 700 from the backside 703. FIGS. 7H-2 and 7H-3 illustrate partial section views corresponding to the cut line Y1-Y1 and cut line Y2-Y2 respectively. FIGS. 7H-4, 7H-5, 7H-6, and 7H-7 illustrate partial section views corresponding to cut line X1-X1, cut line X2-X2, cut line X3-X3, and cut line X4-X4 respectively. In FIGS. 7H-1/7H-2/7H-3/7H-4/7H-5/7H-6/7H-7, a sacrificial layer 728 is deposited on the semiconductor substrate 702 from the backside 703. The sacrificial layer 728 is fully filled in the trench isolations 704 and the tunnels 724. The sacrificial layer 728 can be any suitable sacrificial materials that can be later selectively removed, such as metals (e.g., tungsten (W), copper (Cu), aluminum (Al), etc.), or metal compounds (e.g., titanium nitride (TiN), tantalum nitride (TaN), etc.). The sacrificial layer 728 can be deposited using one or more thin film deposition processes including, but not limited to, CVD, PVD, ALD, or any combination thereof to fully fill the trench isolations 704 and the tunnels 724.

FIG. 7I-1 illustrates an enlarged plan view of one of the sections of the semiconductor memory device 700 from the backside 703. FIGS. 7I-2 and 7I-3 illustrate partial section views corresponding to the cut line Y1-Y1 and cut line Y2-Y2 respectively. FIGS. 7I-4, 7I-5, 7I-6, and 7I-7 illustrate partial section views corresponding to cut line X1-X1, cut line X2-X2, cut line X3-X3, and cut line X4-X4 respectively. In FIGS. 7I-1/7I-2/7I-3/7I-4/7I-5/7I-6/7I-7, excessive sacrificial material of the sacrificial layer 728, and excessive dielectric materials of the thin spacer layer 726 are removed from the surface of the backside 703. In some implementations, a planarization process, such as CMP, is performed to remove the excessive material.

FIG. 7J-1 illustrates an enlarged plan view of one of the sections of the semiconductor memory device 700 from the backside 703. FIGS. 7J-2 and 7J-3 illustrate partial section views corresponding to the cut line Y1-Y1 and cut line Y2-Y2 respectively. FIGS. 7J-4, 7J-5, 7J-6, and 7J-7 illustrate partial section views corresponding to cut line X1-X1, cut line X2-X2, cut line X3-X3, and cut line X4-X4 respectively. In FIGS. 7J-1/7J-2/7J-3/7J-4/7J-5/7J-6/7J-7, an insulating layer 730 is formed on the backside 703 of the semiconductor substrate 702. The insulating layer 730 selectively covers the semiconductor structures 707 and trench isolations 704 within the trench recess region 727. That is, the insulating layer 730 overlaps with the trench recess regions 727. In other words, portions 731 of the backside 703 that are not covered by the insulating layer 730 are smaller than the respective trench recess region 727. As shown in FIGS. 7J-4 and 7J-5, the insulating layer 730 also covers the abnormally higher regions 713 of the word line 712. This way, the word lines 712 are protected from any accidental etching. Portions 731 not covered by the insulating layer 730 are selected as where the bit line of the semiconductor memory device 700 will be formed in a later process. In some implementations, the insulating layer 730 can include any suitable insulating materials, such as silicon oxide, to be deposited on the backside 703 using one or more thin film deposition processes including, but not limited to, CVD, PVD, ALD, or any combination thereof. In some implementations, a planarization process, such as CMP, is performed to remove excess insulating material. A lithography process can be performed to pattern the insulating layer 730 to selectively cover the backside 703 and have portions 731 not covered by using an etch mask (e.g., a photoresist mask and/or a hard mask), for example, based on the design of bit lines. One or more dry etching and/or wet etching processes, such as RIE, can be performed on the insulating layer 730 to etch away portions 731.

FIG. 7K-1 illustrates an enlarged plan view of one of the sections of the semiconductor memory device 700 from the backside 703. FIG. 7K-2 illustrates partial section views corresponding to the cut line Y1-Y1. FIG. 7K-3 illustrates partial section views between cut lines Y2-Y2 and Y4-Y4. FIGS. 7J-4 and 7J-6 illustrate partial section views corresponding to cut line X1-X1 and cut line X3-X3 respectively. FIG. 7K-5 illustrates partial section views between cut lines X1-X1 and X2-X2. FIG. 7K-7 illustrates partial section views between cut lines X3-X3 and X4-X4. In FIGS. 7K-1/7K-2/7K-3/7K-4/7K-5/7K-6/7K-7, bit lines 732 are formed on the exposed semiconductor structures 707 followed by the removal of the sacrificial layer 728. The semiconductor structures 707 exposed in the portions 730 can be doped with N-type dopants (e.g., P or As) or P-type dopants (e.g., B or Ga) at a desired doping level, by performing an implantation process, a thermal diffusion process, a combination thereof, or any suitable processes. In some implementations, the backside 703 of the semiconductor substrate 702 can be pre-doped in an earlier process. The doping discussed above can be used to further adjust the doping level of the semiconductor structures 707. In some implementations, the doping operation can be skipped.

A metal layer can be deposited on top of the semiconductor structures 707 to fill the portions 731. The metal layer can include W, Co, Cu, Al, or any other suitable metals having higher conductivities than the doped substrate. A high-temperature annealing process can be performed on the semiconductor substrate 702 (e.g., a silicon substrate) to form metal silicide (i.e., bit lines 732) on semiconductor structures 707. Metal atoms in the metal layer are diffused into the underlying semiconductor structures 707 (i.e., the silicon substrate) to form the metal silicide (i.e., bit lines 732). The metal atoms would not react when in contact with the sacrificial layer 728 as the sacrificial material is selected to be metal or metal compound as described in FIG. 7H-1.

A metal removal process can be performed to remove any excess metal layer and the sacrificial layer 728. One or more dry etching and/or wet etching processes, such as RIE, can be performed to etch away the remaining metal layer and the sacrificial layer 728. As shown in FIGS. 7K-5 and 7K-7, the sacrificial layer 728 covered by the insulating layer 730 below the covered respective semiconductor structures 707 can be removed by allowing the selective etchant flow through tunnels 724. The abnormally higher regions 713 of the word line 712 are protected by the insulating layer 730 while all sacrificial material of the sacrificial layer 728 are etched away.

By utilizing an overlap between the trench recess region 727 and the insulating layer 730 while introducing a tunnel structure (i.e., tunnels 724), all sacrificial material can be removed which avoids current leakage from any non-removed sacrificial material. In addition, the abnormally higher regions 713 of the word line 712 are protected by the insulating layer 730 from being accidentally etched away during the removal of the sacrificial layer 728 to prevent the word line missing issue.

### III. Flowchart of Fabrication Process to Protect Word Line in Backside Process

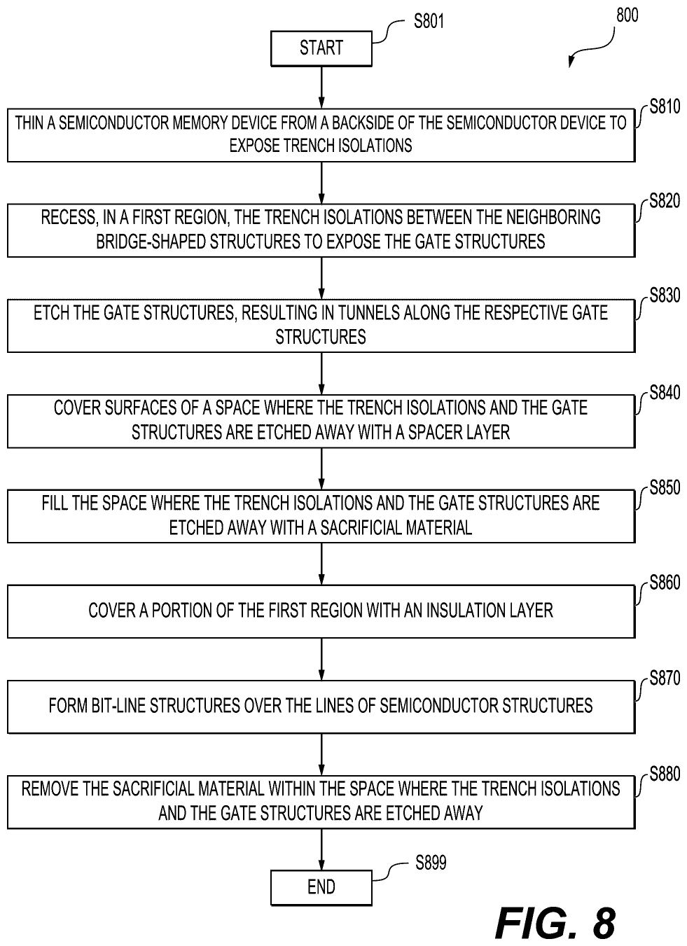

FIG. 8 illustrates a flowchart of a fabrication process 800 for forming a 3D memory device including vertical transistors, according to some aspects of the present disclosure. The fabrication process 800 is just an example of various methods and techniques disclosed in this disclosure. Not all steps are performed in various embodiments. The steps can be carried out in different orders or in parallel in various embodiments. The fabrication process 800 starts from S801 and proceeds to S810.

At S810, a semiconductor memory device can be thinned from a backside of the semiconductor device to expose trench isolations. The semiconductor memory device can have the trench isolations formed in a bit-line direction, gate structures formed in a word-line direction perpendicular to the bit-line direction, and an array of vertical-transistor channel structures that extend in a vertical direction perpendicular to the bit-line direction and the word-line direction and are separated by the trench isolations and the gate structures. After the thinning, the trench isolations are exposed at the back of the semiconductor device. Top ends of the vertical-transistor channel structures in each column along the bit-line direction are connected with a line of semiconductor structure extending along the bit-line direction at the backside of the semiconductor memory device to form a bridge-shaped structure. The trench isolations separate neighboring bridge-shaped structures. The semiconductor memory device can further have metal shields formed between every two neighboring channel structures along the word-line direction.

At S820, the trench isolations between the neighboring bridge-shaped structures can be recessed in a first region of the backside of the semiconductor memory device to expose the gate structures formed in the word-line direction.

At S830, the gate structures formed in the word-line direction can be etched, resulting in tunnels along the respective gate structures. The tunnels cross below each line of semiconductor structures.

At S840, surfaces of a space where the trench isolations and the gate structures are etched away can be covered with a spacer layer.

At S850, the space where the trench isolations and the gate structures are etched away can be filled with a sacrificial material over the spacer layer.

At S860, a portion of the first region of the backside of the semiconductor memory device can be covered with an insulation layer. The insulation layer can enclose the sacrificial materials below the insulation layer and between the respective neighboring bridge-shaped structures at the covered portion of the first region. The insulation layer can cover a second region neighboring the portion of the first region covered by the insulation layer, and the trench isolations in the second region are maintained while the trench isolations in the first region are etched.

At S870, bit-line structures can be formed over the lines of semiconductor structures not covered by the insulation layer in the first region while the portion of the first region is covered with the insulation layer.

At S880, the sacrificial material within the space where the trench isolations and the gate structures are etched away can be removed while the portion of the first region is covered with the insulation layer. The sacrificial material enclosed by the insulation layer is removed through the tunnels crossing below the respective lines of semiconductor structures. The process proceeds to S899 and terminates at S899.

While aspects of the present disclosure have been described in conjunction with the specific embodiments thereof that are proposed as examples, alternatives, modifications, and variations to the examples may be made. Accordingly, embodiments as set forth herein are intended to be illustrative and not limiting. There are changes that may be made without departing from the scope of the claims set forth below.

What is claimed is:

1. A method of fabricating a semiconductor memory device, comprising:
thinning the semiconductor memory device from a backside of the semiconductor device that, at current stage, has trench isolations formed in a bit-line direction, gate structures formed in a word-line direction perpendicular to the bit-line direction, and an array of vertical-transistor channel structures that extend in a vertical direction perpendicular to the bit-line direction and the word-line direction and are separated by the trench isolations and the gate structures, wherein after the thinning, the trench isolations are exposed at the back of the semiconductor device, top ends of the vertical-transistor channel structures in each column along the bit-line direction are connected with a line of semiconductor structure extending along the bit-line direction at the backside of the semiconductor memory device to form a bridge-shaped structure, and the trench isolations separate neighboring bridge-shaped structures;
recessing, in a first region of the backside of the semiconductor memory device, the trench isolations between the neighboring bridge-shaped structures to expose the gate structures formed in the word-line direction;
etching the gate structures formed in the word-line direction, resulting in tunnels along the respective gate structures, the tunnels crossing below each line of semiconductor structure;
filling a space where the trench isolations and the gate structures are etched away with a sacrificial material;
covering a portion of the first region of the backside of the semiconductor memory device with an insulation layer, the insulation layer enclosing the sacrificial materials below the insulation layer and between the respective neighboring bridge-shaped structures at the covered portion of the first region; and
removing the sacrificial material within the space where the trench isolations and the gate structures are etched away while the portion of the first region is covered with the insulation layer, wherein the sacrificial material enclosed by the insulation layer is removed through the tunnels crossing below respective lines of semiconductor structures.

2. The method of claim 1, wherein the insulation layer covers a second region neighboring the portion of the first region covered by the insulation layer, and the trench isolations in the second region are maintained while the trench isolations in the first region are etched.

3. The method of claim 1, wherein the semiconductor memory device has metal shields formed between every two neighboring channel structures along the word-line direction.

4. The method of claim 3, further comprising:
etching the metal shields formed in the word-line direction, resulting in tunnels along the respective metal shield crossing below each line of semiconductor structure;
filling the space where the trench isolations and the metal shields are etched away with the sacrificial material; and
removing the sacrificial material within the space where the trench isolations and the metal shields are etched away while the portion of the first region is covered with the insulation layer, wherein the sacrificial material enclosed by the insulation layer is removed through the tunnels along the respective metal shields crossing below respective lines of semiconductor structures.

5. The method of claim 1, further comprising:
covering surfaces of the space where the trench isolations and the gate structures are etched away with a spacer layer before filling the space where the trench isolations and the gate structures are etched away with the sacrificial material.

6. The method of claim 1, further comprises:
forming bit-line structures over the lines of semiconductor structures not covered by the insulation layer in the first region while the portion of the first region is covered with the insulation layer.

7. A semiconductor memory device, comprising:
trench isolations arranged in a bit-line direction;
gate structures arranged in a word-line direction perpendicular to the bit-line direction;
an array of vertical-transistor channels arranged in a vertical direction perpendicular to the bit-line direction and the word-line direction and separated by the trench isolations and gate structures, top ends of the array of the vertical-transistor channels in each column being connected to a line of semiconductor structure extending in the bit-line direction at a backside of the semiconductor memory device; and
air gap tunnels along the word-line direction that each crosses below the line of semiconductor structure and between two neighboring vertical-transistor channels in a first region at the backside of the semiconductor memory device.

8. The semiconductor memory device of claim 7, wherein the air gap tunnels are adjacent to the gate structures.

9. The semiconductor memory device of claim 7, further comprises metal shields between every two neighboring vertical-transistor channels along the word-line direction.

10. The semiconductor memory device of claim 9, wherein the air gap tunnels are adjacent to the metal shields.

11. The semiconductor memory device of claim 7, wherein a surface of at least one of the air gap tunnels is covered by a spacer layer that surrounds an air gap.

12. The semiconductor memory device of claim 7, wherein top portions of the trench isolation at the backside of the semiconductor memory device are recessed to form air gaps above the trench isolation and between bridge-shaped structures each formed by the respective line of semiconductor structure and the respective vertical-transistor channels in the respective column, and the air gaps are connected with the air gap tunnels.

13. The semiconductor memory device of claim 12, wherein a spacer layer covers surfaces of the air gaps between bridge-shaped structures each formed by the respective line of semiconductor structure and the respective vertical-transistor channels in the respective column and the air gap tunnels connected with the air gap tunnels.

14. The semiconductor memory device of claim 7, wherein an insulation layer covers a portion of the first region and a second region neighboring the portion of the first region, and no air gap tunnel is formed within the second region.

15. A memory system, comprising:
a memory controller; and
a semiconductor memory device coupled to the memory controller, the semiconductor memory device comprising:
trench isolations arranged in a bit-line direction;
gate structures arranged in a word-line direction perpendicular to the bit-line direction;
an array of vertical-transistor channels arranged in a vertical direction perpendicular to the bit-line direction and the word-line direction and separated by the trench isolations and gate structures, top ends of the array of the vertical-transistor channels in each column being connected to a line of semiconductor structure extending in the bit-line direction at a backside of the semiconductor memory device; and
air gap tunnels along the word-line direction that each crosses below the line of semiconductor structure and between two neighboring vertical-transistor channels in a first region at the backside of the semiconductor memory device.

16. The memory system of claim 15, wherein the air gap tunnels are adjacent to the gate structures.

17. The memory system of claim 15, further comprises metal shields between every two neighboring vertical-transistor channels along the word-line direction.

18. The memory system of claim 17, wherein the air gap tunnels are adjacent to the metal shields.

19. The memory system of claim 15, wherein a surface of at least one of the air gap tunnels is covered by a spacer layer that surrounds an air gap.

20. The memory system of claim 15, wherein top portions of the trench isolation at the backside of the semiconductor memory device are recessed to form air gaps above the trench isolation and between bridge-shaped structures each formed by the respective line of semiconductor structure and the respective vertical-transistor channels in the respective column, and the air gaps are connected with the air gap tunnels, wherein
a spacer layer covers surfaces of the air gaps between bridge-shaped structures each formed by the respective line of semiconductor structure and the respective vertical-transistor channels in the respective column and the air gap tunnels connected with the air gap tunnels.
